(19) United States
(12) Patent Application Publication
(10) Pub. No.: US 2021/0210452 A1
(43) Pub. Date: Jul. 8, 2021

(54) INTEGRATED PASSIVE DEVICE (IPD) COUPLED TO FRONT SIDE OF INTEGRATED DEVICE

(71) Applicant: QUALCOMM Incorporated, San Diego, CA (US)

(72) Inventors: Abdolreza LANGARI, San Diego, CA (US); Periannan CHIDAMBARAM, San Diego, CA (US); Lisha ZHANG, San Diego, CA (US); Jonghae KIM, San Diego, CA (US)

(21) Appl. No.: 16/987,122

(22) Filed: Aug. 6, 2020

Related U.S. Application Data
(60) Provisional application No. 62/956,535, filed on Jan. 2, 2020.

(51) Int. Cl. H01L 23/00; H01L 23/538; H01L 23/28; H01L 23/488

(52) U.S. Cl. CPC H01L 24/14; H01L 23/488; H01L 23/28; H01L 23/5386

(57) ABSTRACT

A device that includes an integrated device, a plurality of solder interconnects, and an integrated passive device (IPD). The integrated device includes a die having a front side and back side, and a metallization portion coupled to the front side of the die. The metallization portion includes at least one metallization layer and a plurality of under bump metallization (UBM) interconnects. The plurality of solder interconnects is coupled to the metallization portion. The integrated passive device (IPD) is coupled to the metallization portion of the integrated device such that the IPD is located between at least two solder interconnects from the plurality of solder interconnects.

### CROSS-REFERENCE/CLAIM OF PRIORITY TO RELATED APPLICATION

The present application claims priority to and the benefit of U.S. Provisional Application No. 62/956,535, filed on Jan. 2, 2020, and titled, “INTEGRATED PASSIVE DEVICE (IPD) COUPLED TO FRONT SIDE OF INTEGRATED DEVICE”, which is hereby expressly incorporated by reference.

### FIELD

Various features relate to integrated devices and integrated passive devices (IPDs), but more specifically to an IPD coupled to a front side of an integrated device.

### BACKGROUND

FIG. 1 illustrates a package 100 that includes a substrate 102, an integrated device 104, and an encapsulation layer 108. The substrate 102 includes a plurality of dielectric layers 120, a plurality of interconnects 122, and a plurality of solder interconnects 124. A plurality of solder interconnects 144 is coupled to the substrate 102 and the integrated device 104. The encapsulation layer 108 encapsulates the integrated device 104 and the plurality of solder interconnects 144. The package 100 and a passive device 130 are coupled to the board 190. The passive device 130 is located next to the package 100. The location of the passive device 130 may not help provide optimal performance for the package 100 since the passive device 130 is located relatively far away from the package 100. There is an ongoing need to provide packages and passive devices that improve the overall performance of the package.

### SUMMARY

Various features relate to integrated devices and integrated passive devices (IPDs), but more specifically to an IPD coupled to a front side of an integrated device.

One example provides a device that includes an integrated device, a plurality of solder interconnects, and an integrated passive device (IPD). The integrated device includes a metallization portion. The metallization portion includes at least one metallization layer and a plurality of under bump metallization (UBM) interconnects. The device includes a plurality of solder interconnects coupled to the metallization portion. The device includes an integrated passive device (IPD) coupled to the metallization portion. The IPD is located laterally between at least two solder interconnects from the plurality of solder interconnects.

Another example provides a device that includes an integrated device, a plurality of pillar interconnects coupled to the integrated device, and an integrated passive device (IPD) coupled to the integrated device such that the IPD is located laterally between at least two pillar interconnects from the plurality of pillar interconnects.

Another example provides a device that includes an integrated device, a plurality of pillar interconnects coupled to the integrated device, and a passive device interposer coupled to the integrated device and the plurality of pillar interconnects. The passive device interposer includes an integrated passive device (IPD), an encapsulation layer, an interconnect coupled to the IPD, and a solder interconnect coupled the interconnect and to at least one pillar interconnect from the plurality of pillar interconnects.

Another example provides an apparatus that includes an integrated device comprising a metallization portion, a plurality of solder interconnects coupled to the metallization portion. The metallization portion includes at least one metallization layer and a plurality of under bump metallization (UBM) interconnects. The apparatus includes means for passive operation coupled to the metallization portion. The means for passive operation is located laterally between at least two solder interconnects from the plurality of solder interconnects.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a package and a passive device coupled to a board.

FIG. 2 illustrates a profile view of an exemplary integrated passive device coupled to a front side of an integrated device.

FIG. 3 illustrates a bottom plan view of an exemplary integrated passive device coupled to a front side of an integrated device.

FIG. 4 illustrates a bottom plan view of an exemplary integrated passive device coupled to a front side of an integrated device.

FIG. 5 illustrates a profile view of an exemplary integrated passive device coupled to a front side of an integrated device.

FIG. 6 illustrates a profile view of an exemplary integrated passive device coupled to a front side of an integrated device.

FIG. 7 illustrates a profile view of an exemplary integrated passive device coupled to a front side of an integrated device.

FIG. 8 illustrates a profile view of an exemplary integrated passive device coupled to a front side of an integrated device.

FIG. 9 illustrates a profile view of an exemplary integrated passive device coupled to a front side of an integrated device.

FIG. 10 illustrates a profile view of an exemplary integrated passive device coupled to a front side of an integrated device.

FIGS. 11A-11D illustrate an exemplary sequence for fabricating an integrated device comprising an integrated passive device coupled to a front side of the integrated device.

FIG. 12 illustrates an exemplary flow diagram of a method for fabricating an integrated device comprising an integrated passive device coupled to a front side of the integrated device.

FIG. 13 illustrates a profile view of an exemplary integrated passive device coupled to a front side of an integrated device.

FIG. 14 illustrates a profile view of an exemplary integrated passive device coupled to a front side of an integrated device.

FIG. 15 illustrates a profile view of an exemplary integrated passive device coupled to a front side of an integrated device.

FIG. 16 illustrates a profile view of an exemplary integrated passive device coupled to a front side of an integrated device.

FIGS. 17A-17B illustrate an exemplary sequence for fabricating a passive device interposer.

FIG. 18 illustrates an exemplary flow diagram of a method for fabricating a passive device interposer.

FIG. 19 illustrates an exemplary sequence for fabricating an integrated device comprising a passive device interposer coupled to a front side of the integrated device.

FIG. 20 illustrates an exemplary flow diagram of a method for fabricating an integrated device comprising a passive device interposer coupled to a front side of the integrated device.

FIG. 21 illustrates a profile view of an exemplary integrated passive device coupled to an integrated device.

FIG. 22 illustrates a profile view of an exemplary integrated passive device coupled to a redistribution portion of an integrated device.

FIG. 23 illustrates various electronic devices that may integrate a die, an integrated device, an integrated passive device (IPD), a device package, a package, an integrated circuit and/or PCB described herein.

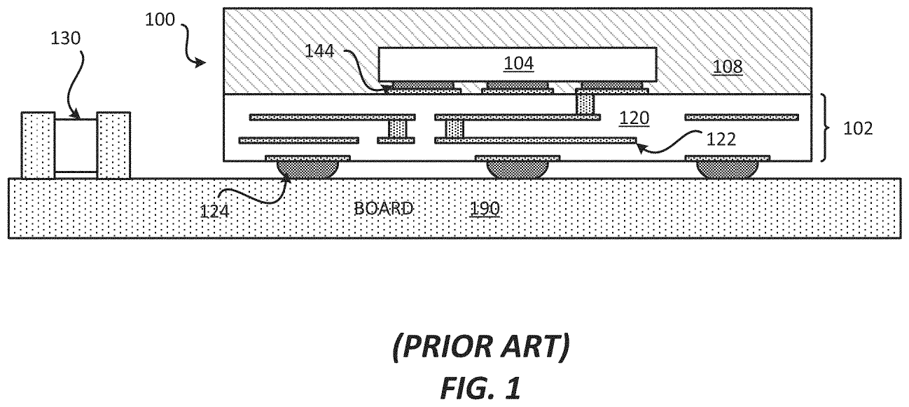

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a device that includes an integrated device, a plurality of solder interconnects, and an integrated passive device (IPD). The integrated device includes a die having a front side and back side, and a metallization portion (e.g., redistribution portion) coupled to the front side of the die. The integrated device may include a wafer level package (WLP). The metallization portion includes at least one metallization layer (e.g., at least one redistribution layer (RDL)) and a plurality of under bump metallization (UBM) interconnects. The plurality of solder interconnects is coupled to the metallization portion. The integrated passive device (IPD) is coupled to the metallization portion of the integrated device such that the IPD is located laterally between at least two solder interconnects from the plurality of solder interconnects. The IPD may be coupled to the metallization portion through a first solder interconnect and a second solder interconnect. The IPD may be coupled to a first UBM interconnect through the first solder interconnect, and a second UBM interconnect through the second solder interconnect. In some implementations, the IPD may be coupled to a first metallization interconnect through the first solder interconnect, and a second metallization interconnect through the second solder interconnect. In some implementations, the IPD may be coupled to a first UBM interconnect through the first solder interconnect, and a second UBM interconnect through the second solder interconnect. The IPD may be a die that includes one or more passive components integrated in the die. One advantage of this configuration is that the passive device is a lot closer to the die, which may help improve the overall performance of the die and the integrated device. For example, placing the passive device closer to the die may help reduce the voltage droop (e.g., IR droop) to one or more transistors of the integrated device. A reduction in the voltage droop may mean that the transistors receive more voltage, and therefore can operate faster.

### Exemplary Integrated Device Coupled to Integrated Passive Device (IPD)

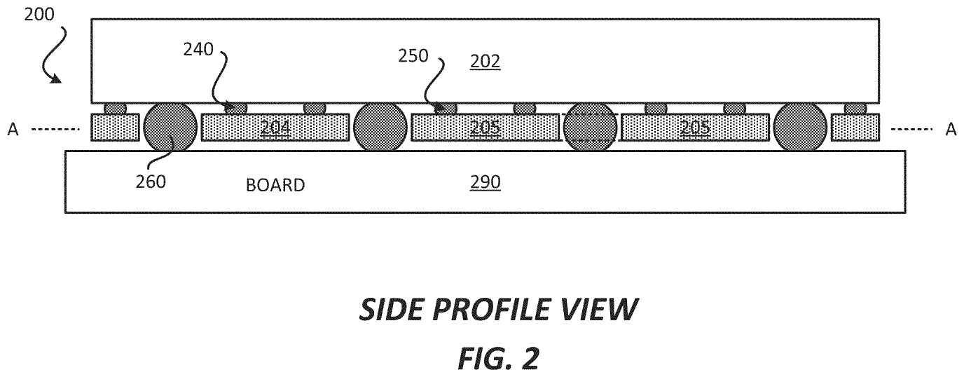

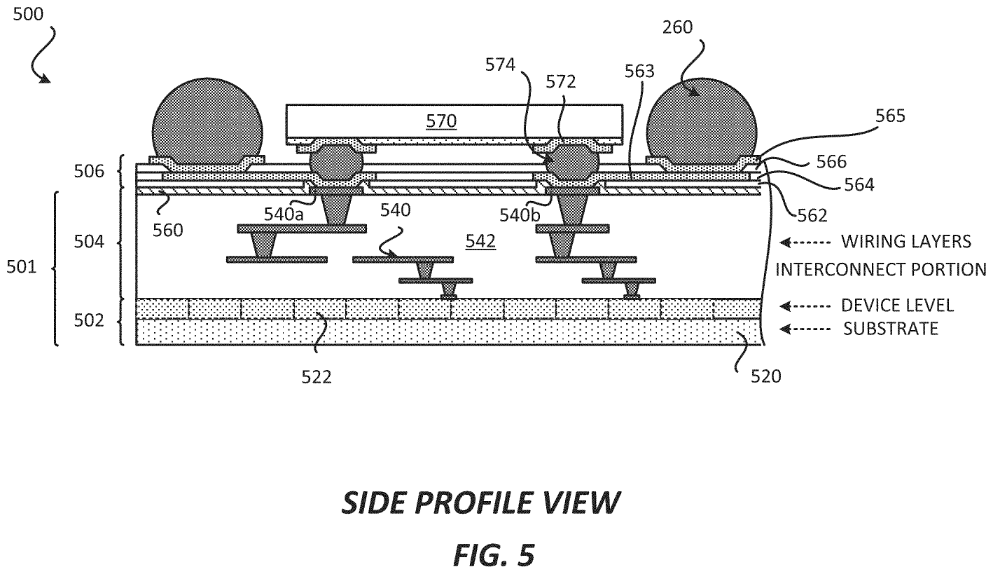

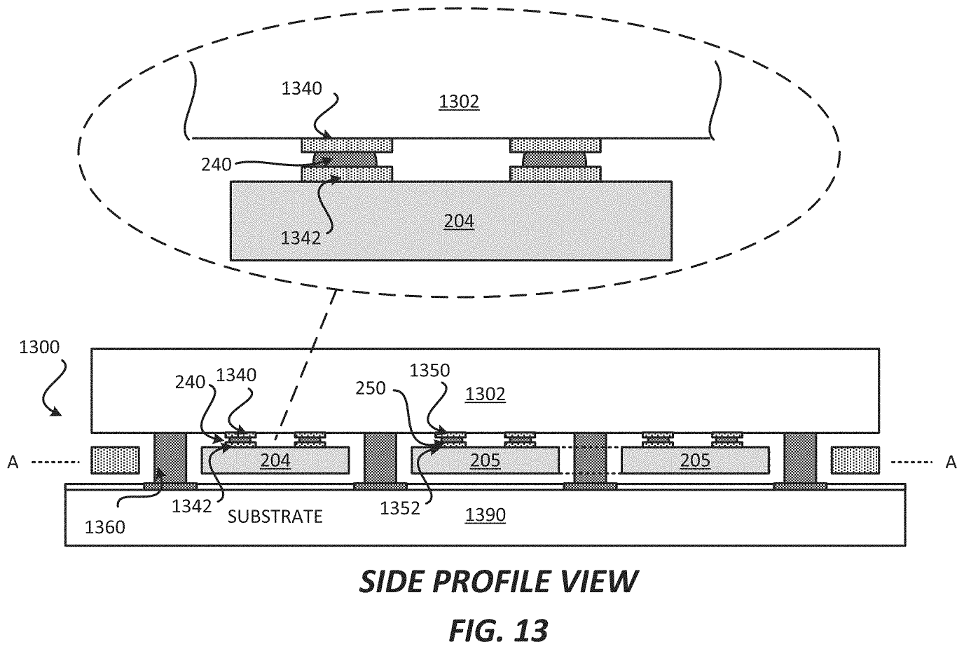

FIG. 2 illustrates an example of a device 200 that includes an integrated device 202, an integrated passive device (IPD) 204, and an IPD 205. The integrated device 202 may include a front side and a back side. The integrated device 202 may include a die (e.g., semiconductor bare die). As will be further described below, the integrated device 202 may include a die and a metallization portion (e.g., redistribution portion). A plurality of solder interconnects 260 is coupled to the front side of the integrated device. The integrated device 202 is coupled to a board 290 (e.g., printed circuit board (PCB)) through the plurality of solder interconnects 260. The IPD 204 and the IPD 205 are coupled to the front side of the integrated device 202. The IPD 204 is coupled to the front side of the integrated device 202 through a plurality of solder interconnects 240. The IPD 205 is coupled to the front side of the integrated device 202 through a plurality of solder interconnects 250. The IPD 204 and the IPD 205 are located between the integrated device 202 and the board 290. FIG. 2 also illustrates that the IPD 204 and the IPD 205 are each located laterally between two solder interconnects from the plurality of solder interconnects 260. The IPD 205 may laterally surround at least one solder interconnect from the plurality of solder interconnects 260. For example, the IPD 205 may include a cavity through which a solder interconnect may extend through. More specific examples of IPDs coupled to an integrated device are further described below in at least FIGS. 5-10 and 13-16. As will be further described below in at least FIGS. 13-16, in some implementations, the integrated device may be coupled to a board and/or a substrate through a plurality of pillar interconnects.

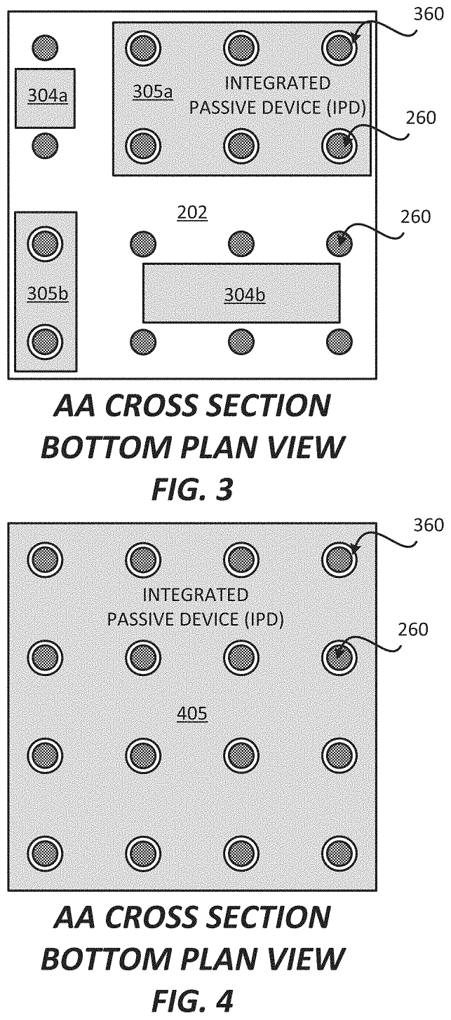

FIG. 3 illustrates a bottom plan view of several IPDs coupled to an integrated device. The bottom plan view of FIG. 3 may be exemplary of a view across the AA cross-section of FIG. 2. As shown in FIG. 3, an IPD 304a, an IPD 304b, an IPD 305a and an IPD 305b are coupled to a front side of the integrated device 202. Each of the IPD 304a, the IPD 304b, the IPD 305a and the IPD 305b has a lateral size (or footprint) that is less than the lateral size of the integrated device 202. One of more of the IPD 304a, the IPD 304b, the IPD 305a and/or the IPD 305b may include a die that is configured to operate as a passive device. One of more of the IPD 304a, the IPD 304b, the IPD 305a and/or the IPD 305b may include a system on chip (SoC) that is configured to operate as a passive device. The IPD 304a and the IPD 304b may be the similar or the same as the IPD 204 of FIG. 2. The IPD 305a and the IPD 305b may be similar or the same as the IPD 205 of FIG. 2. The IPD may be means for passive operation.

The IPD 304a and the IPD 304b are each located between at least two solder interconnects from the plurality of solder interconnects 260. The IPD 305a and the IPD 305b, each includes a plurality of cavities 360. The plurality of cavities 360 (e.g., one or more cavities) allows solder interconnects to extend through the IPD, when the IPD is coupled to the integrated device 202. Different implementations may have a different number of cavities for each IPD. When the plurality of solder interconnects 260 extends through the cavities 360, one or more IPDs may laterally surround one or more solder interconnects. When the plurality of solder interconnects 260 extends through the cavities 360, the solder interconnects may not be touching the inside walls of the IPD (e.g., 305a, 305b), leaving a lateral gap (e.g., void) between the solder interconnect and the IPD.

FIG. 4 illustrates a bottom plan view of an IPD coupled to the integrated device. The bottom plan view of FIG. 4 may be exemplary of a view across the AA cross-section of FIG. 2. As shown in FIG. 4, an IPD 405 is coupled to a front side of an integrated device (e.g., 202). In this example, the lateral size (or footprint) of the IPD 405 is approximately the same size as the lateral size of the integrated device. The IPD 405 may include a die that is configured to operate as a passive device (e.g., capacitor, inductor, resistor, transformer). The IPD 405 may include a system on chip (SoC) that is configured to operate as a passive device. The IPD 405 may be similar or the same as the IPD 205 of FIG. 2. The IPD 405 may be means for passive operation.

In some implementations, the IPDs (e.g., 204, 205, 304a, 304b, 305a, 305b, 405) may be considered as a passive device interposer (e.g., capacitor interposer layer) for the integrated device.

Having described IPDs that are coupled to a front side of an integrated device, more specific examples of IPDs coupled to a front side of an integrated device will be further described below.

### Exemplary Integrated Device Coupled to Integrated Passive Device (IPD)

FIG. 5 illustrates an integrated passive device coupled to an integrated device. In particular, FIG. 5 illustrates an integrated passive device (IPD) 570 coupled to an integrated device 500. In some implementations, the IPD 570 may be considered part of the integrated device 500. In some implementations, the IPD 570 and the integrated device 500 may be considered part of the same device. The IPD 570 may be a more specific implementation of the IPD (e.g., 204, 304a, 304b) of FIGS. 2-4. The integrated device 500 may be a more specific implementation of the integrated device 202. The integrated device 500 may include a wafer level package (WLP).

The integrated device 500 includes a substrate 520 (e.g., silicon substrate), a plurality of device level cells 522 (e.g., logic cells), an interconnect portion 504, and a redistribution portion 506 (e.g., metallization portion). The plurality of device level cells 522 is formed over the substrate 520. The plurality of device level cells 522 may form the device level layer of the integrated device 500. The plurality of device level cells 522 may include one or more transistors. In some implementations, the plurality of device level cells 522 may include portions of the substrate 520. In some implementations, the substrate 520, the device level layer and the plurality of device level cells 522 may be referred as the substrate portion 502 of the integrated device 500. A front end of line (FEOL) process may be used to fabricate the substrate portion 502.

The interconnect portion 504 is formed over the substrate portion 502. In particular, the interconnect portion 504 is formed over the plurality of device level cells 522. The interconnect portion 504 includes wiring layers (e.g., interconnect layers). The interconnect portion 504 includes a plurality of interconnects 540 (e.g., trace, pad, vias) and at least one dielectric layer 542. The interconnect portion 504 may provide interconnect between the plurality of transistors of the substrate portion 502. A back end of line (BEOL) process may be used to fabricate the interconnect portion 504. In some implementations, the substrate portion 502 and the interconnect portion 504 may be considered a die 501 (e.g., bare semiconductor die). The die 501 may include a front side and back side. The back side of the die 501 may be the side that includes the substrate 520. The front side of the die 501 may be the side that includes the interconnect portion 504.

A redistribution portion 506 is formed and located over the interconnect portion 504. The redistribution portion 506 may be a form a metallization portion that includes at least one metallization layer. The redistribution portion 506 includes a passivation layer 560, a redistribution layer (RDL) 563, a plurality of under bump metallization (UBM) interconnects 565, a dielectric layer 562, a dielectric layer 564 and a dielectric layer 566. The RDL 563 may include a plurality of redistribution interconnects (or RDL interconnects). A first redistribution interconnect from the RDL 563 may be coupled to an interconnect 540a (e.g., pad), and a second redistribution interconnect from the RDL 563 may be coupled to an interconnect 540b (e.g., pad). The RDL 563 (and/or any of the RDLs described in the disclosure) may include redistribution interconnects that include a U-shape or V-shape. The terms “U-shape” and “V-shape” shall be interchangeable. The terms “U-shape” and “V-shape” may refer to the side profile shape of the interconnects and/or redistribution interconnects. The U-shape interconnect and the V-shape interconnect may have a top portion and a bottom portion. A bottom portion of a U-shape interconnect (or a V-shape interconnect) may be coupled to a top portion of another U-shape interconnect (or a V-shape interconnect). The RDL 563 is formed and located over the passivation layer 560. The UBM interconnect 565 is located over and coupled to the RDL 563. The dielectric layer 562, the dielectric layer 564 and the dielectric layer 566 may considered as one dielectric layer or several dielectric layers. The plurality of solder interconnects 260 may be coupled to the UBM interconnect 565. The redistribution portion 506 may be a form of a metallization portion that includes a plurality of interconnects. The redistribution layer (RDL) may be a form of a metallization layer.

The integrated device 500 includes a front side and a back side. The front side of the integrated device 500 may be the side of the integrated device 500 that includes a redistribution portion. The back side of the integrated device 500 may be the side of the integrated device 500 that includes the substrate (e.g., 520). The back side of the integrated device 500 may be opposite to the front side of the integrated device 500. The IPD 570 is coupled to the front side of the integrated device 500. In particular, the IPD 570 is coupled to the redistribution portion 506 of the integrated device 500, such that the IPD 570 is located laterally between at least two solder interconnects from the plurality of solder interconnects 260. In the example of FIG. 5, the IPD 570 is coupled to the RDL 563, through the plurality of passive device solder interconnects 574. The IPD 570 includes the plurality of UBM interconnects 572 (e.g., IPD UBM interconnects). The plurality of UBM interconnects 572 (e.g., IPD UBM interconnects) is coupled to the plurality of passive device solder interconnects 574. In some implementations, a first UBM interconnect (which may be a first terminal) from the IPD 570 is configured for power, and a second UBM interconnect (which may be a second terminal) from the IPD 570 is configured for ground. The IPD 570 may include a die that is configured to operate as a passive device (e.g., capacitor, inductor). The IPD 570 may include a system on chip (SoC) that is configured to operate as a passive device. The IPD 570 may be means for passive operation. The IPD 570 may be fabricated using a FEOL process and/or BEOL process. Different numbers of IPDs with similar or different sizes may be coupled to the integrated device 500. An IPD may include a die substrate, at least one dielectric layer, at least one metal layer and an insulator layer. The use of the IPD(s) between solder interconnects helps reduce the voltage droop (e.g., IR droop) to a transistor, thus more voltage can be applied to a transistor, resulting is better transistor speeds and improved circuit timing. This is because the IPD(s) are located a lot closer to the transistors of the integrated device 500.

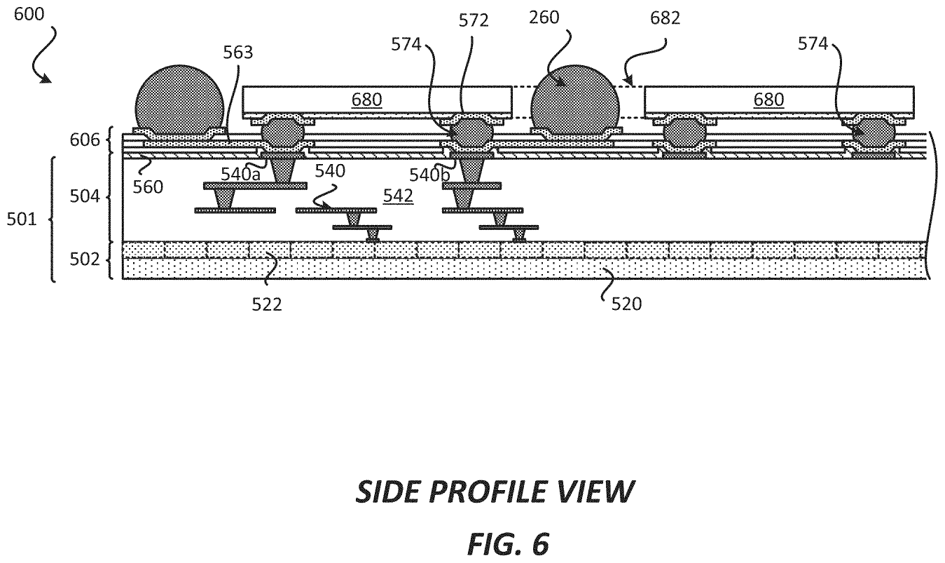

FIG. 6 illustrates an integrated passive device coupled to an integrated device. In particular, FIG. 6 illustrates an integrated passive device (IPD) 680 coupled to an integrated device 600. In some implementations, the IPD 680 may be considered part of the integrated device 600. In some implementations, the IPD 680 and the integrated device 600 may be considered part of the same device. The IPD 680 may be a more specific implementation of the IPD (e.g., 205, 305a, 305b, 405) of FIGS. 2-4. The integrated device 600 may be a more specific implementation of the integrated device 202. The integrated device 600 may include a wafer level package (WLP).

The integrated device 600 may be similar to the integrated device 500, and thus includes similar components as the integrated device 500. The integrated device 600 includes the substrate portion 502, the interconnect portion 504, and a redistribution portion 606. The redistribution portion 606 is similar to the redistribution portion 506, and thus includes similar or the same components as the redistribution portion 506.

The IPD 680 is coupled to the front side of the integrated device 600. In particular, the IPD 680 is coupled to the redistribution portion 606 of the integrated device 600, such that the IPD 680 is located between at least two solder interconnects from the plurality of solder interconnects 260. The IPD 680 includes at least one cavity 682. At least one solder interconnect 260 extends through the at least one cavity 682 of the IPD 680, such that the IPD 680 laterally surrounds the at least one solder interconnect 260. In the example of FIG. 6, the IPD 680 is coupled to the RDL 563, through the plurality of passive device solder interconnects 574, in a similar manner as described in FIG. 5. The IPD 680 may be means for passive operation. Different numbers of IPDs with similar or different sizes may be coupled to the integrated device 600. In the example of FIGS. 5 and 6, the IPDs (e.g., 570, 680) are coupled to the RDL 563 (e.g., redistribution interconnects). However, in some implementations, the IPDs may be coupled to different parts of the redistribution portion (e.g., 506, 606). The redistribution portion 606 may be a form of a metallization portion that includes a plurality of interconnects. The redistribution layer (RDL) may be a form of a metallization layer.

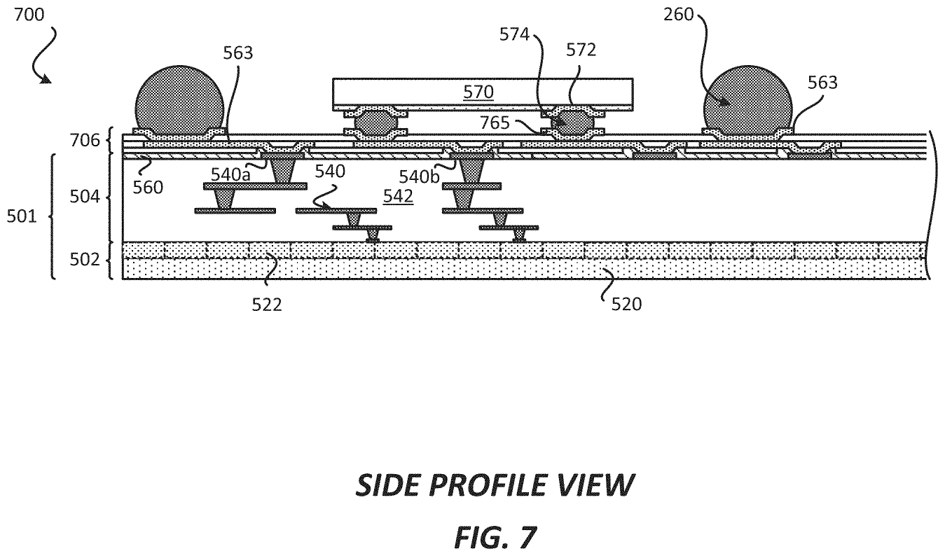

FIG. 7 illustrates an integrated passive device coupled to an integrated device. In particular, FIG. 7 illustrates an integrated passive device (IPD) 570 coupled to an integrated device 700. In some implementations, the IPD 570 may be considered part of the integrated device 700. In some implementations, the IPD 570 and the integrated device 700 may be considered part of the same device. The IPD 570 may be a more specific implementation of the IPD (e.g., 204, 304a, 304b) of FIGS. 2-4. The integrated device 700 may be a more specific implementation of the integrated device 202. The integrated device 700 may include a wafer level package (WLP).

The integrated device 700 may be similar to the integrated device 500, and thus includes similar components as the integrated device 500. The integrated device 700 includes the substrate portion 502, the interconnect portion 504, and a redistribution portion 706. The redistribution portion 706 is similar to the redistribution portion 506, and thus includes similar or the same components as the redistribution portion 506. The redistribution portion 706 may be a form of a metallization portion that includes a plurality of interconnects. The redistribution layer (RDL) may be a form of a metallization layer. The redistribution portion 706 includes a plurality of UBM interconnects 765. The plurality of UBM interconnects 765 is coupled to the RDL 563.

The IPD 570 is coupled to the front side of the integrated device 700. In particular, the IPD 570 is coupled to the redistribution portion 706 of the integrated device 700, such that the IPD 570 is located laterally between at least two solder interconnects from the plurality of solder interconnects 260. In the example of FIG. 7, the IPD 570 is coupled to the UBM interconnects 765, through the plurality of passive device solder interconnects 574. The plurality of UBM interconnects 572 is coupled to the plurality of passive device solder interconnects 574. In some implementations, a first UBM interconnect (which may define a first terminal) from the IPD 570 is configured for power, and a second UBM interconnect (which may define a second terminal) from the IPD 570 is configured for ground.

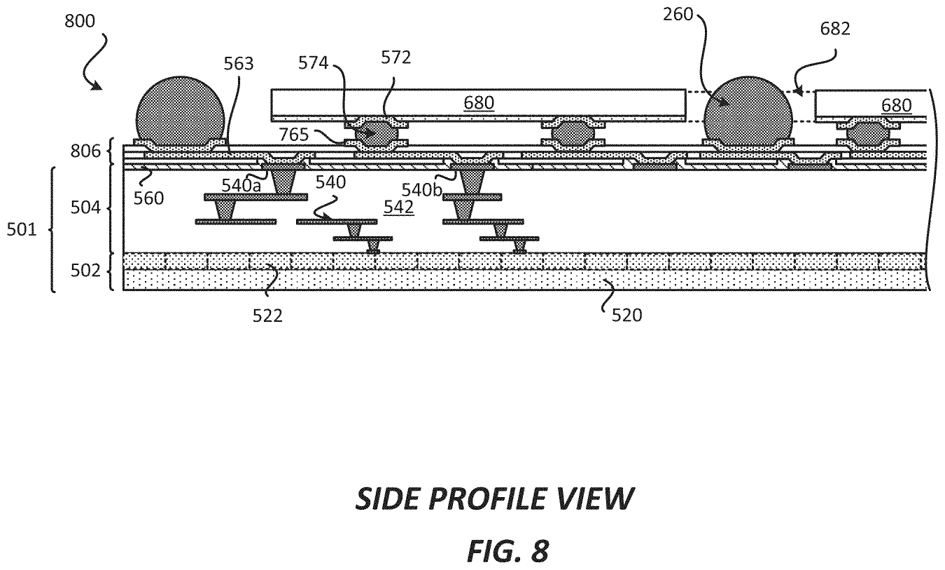

FIG. 8 illustrates an integrated passive device coupled to an integrated device. In particular, FIG. 8 illustrates an integrated passive device (IPD) 680 coupled to an integrated device 800. In some implementations, the IPD 680 may be considered part of the integrated device 800. In some implementations, the IPD 680 and the integrated device 800 may be considered part of the same device. The IPD 680 may be a more specific implementation of the IPD (e.g., 205, 305a, 305b, 405) of FIGS. 2-4. The integrated device 800 may be a more specific implementation of the integrated device 202. The integrated device 800 may include a wafer level package (WLP).

The integrated device 800 may be similar to the integrated device 700, and thus includes similar components as the integrated device 700. The integrated device 800 includes the substrate portion 502, the interconnect portion 504, and a redistribution portion 806. The redistribution portion 806 is similar to the redistribution portion 506 (and/or the redistribution portion 706), and thus includes similar or the same components as the redistribution portion 506 (and/or the redistribution portion 706). The redistribution portion 806 may be a form of a metallization portion that includes a plurality of interconnects. The redistribution layer (RDL) may be a form of a metallization layer.

The IPD 680 is coupled to the front side of the integrated device 800. In particular, the IPD 680 is coupled to the redistribution portion 806 of the integrated device 800, such that the IPD 680 is located between at least two solder interconnects from the plurality of solder interconnects 260. The IPD 680 includes at least one cavity 682. At least one solder interconnect 260 extends through the at least one cavity 682 of the IPD 680, such that the IPD 680 laterally surrounds the at least one solder interconnect 260. In the example of FIG. 6, the IPD 680 is coupled to the plurality of UBM interconnects 765, through the plurality of passive device solder interconnects 574, in a similar manner as described in FIG. 7.

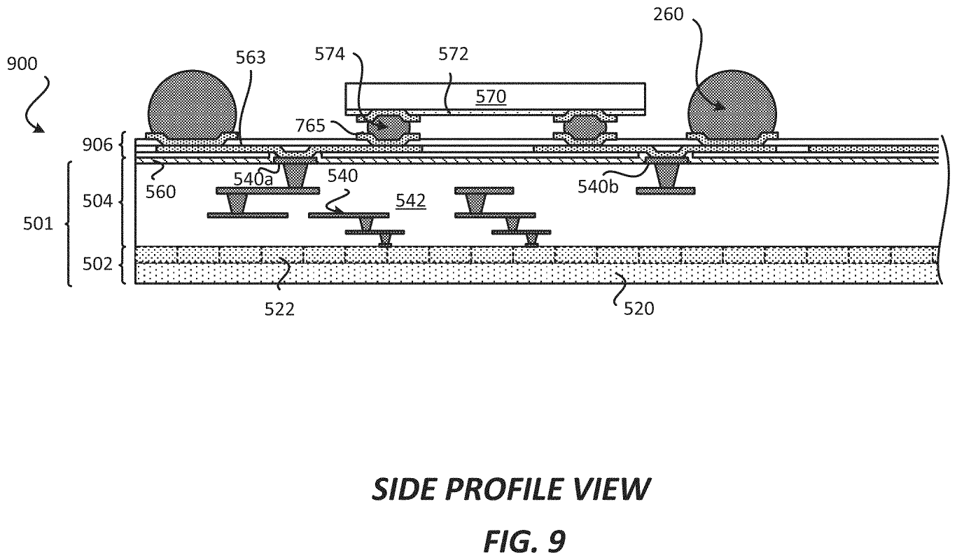

FIG. 9 illustrates an integrated passive device coupled to an integrated device. In particular, FIG. 9 illustrates an integrated passive device (IPD) 570 coupled to an integrated device 900. In some implementations, the IPD 570 may be considered part of the integrated device 900. In some implementations, the IPD 570 and the integrated device 900 may be considered part of the same device. The IPD 570 may be a more specific implementation of the IPD (e.g., 204, 304a, 304b) of FIGS. 2-4. The integrated device 900 may be a more specific implementation of the integrated device 202. The integrated device 900 may include a wafer level package (WLP).

The integrated device 900 may be similar to the integrated device 700, and thus includes similar components as the integrated device 700. The integrated device 900 includes the substrate portion 502, the interconnect portion 504, and a redistribution portion 906. The redistribution portion 906 is similar to the redistribution portion 706, and thus includes similar or the same components as the redistribution portion 706. The redistribution portion 906 may be a form of a metallization portion that includes a plurality of interconnects. The redistribution layer (RDL) may be a form of a metallization layer. The redistribution portion 906 includes a plurality of UBM interconnects 765. The plurality of UBM interconnects 765 is coupled to the RDL 563.

The IPD 570 is coupled to the front side of the integrated device 900. In particular, the IPD 570 is coupled to the redistribution portion 906 of the integrated device 900, such that the IPD 570 is located between at least two solder interconnects from the plurality of solder interconnects 260. In the example of FIG. 9, the IPD 570 is coupled to the UBM interconnects 765, through the plurality of passive device solder interconnects 574. The plurality of UBM interconnects 572 is coupled to the plurality of passive device solder interconnects 574. In some implementations, a first UBM interconnect from the IPD 570 is configured for power, and a second UBM interconnect from the IPD 570 is configured for ground.

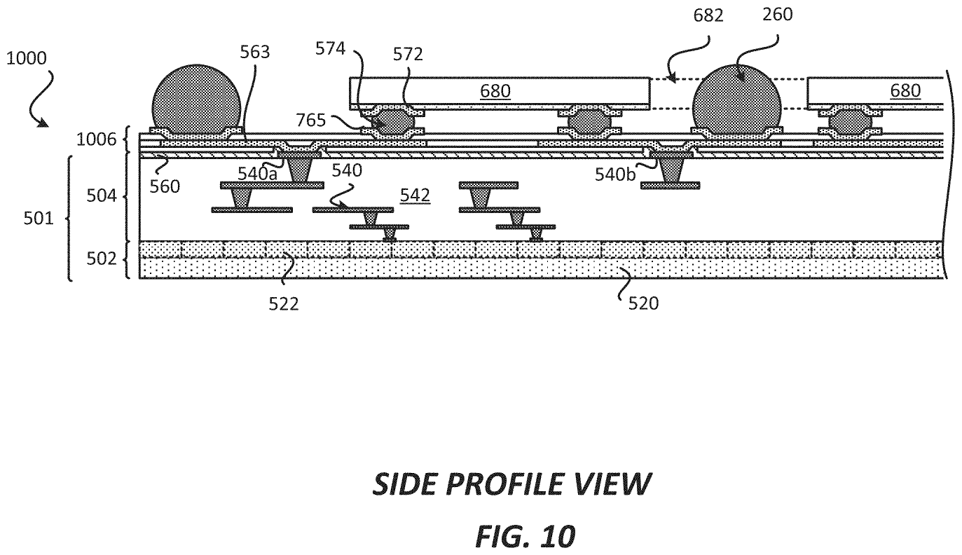

FIG. 10 illustrates an integrated passive device coupled to an integrated device. In particular, FIG. 10 illustrates an integrated passive device (IPD) 680 coupled to an integrated device 1000. In some implementations, the IPD 680 may be considered part of the integrated device 1000. In some implementations, the IPD 680 and the integrated device 1000 may be considered part of the same device. The IPD 680 may be a more specific implementation of the IPD (e.g., 205, 305a, 305b, 405) of FIGS. 2-4. The integrated device 1000 may be a more specific implementation of the integrated device 202. The integrated device 1000 may include a wafer level package (WLP).

The integrated device 1000 may be similar to the integrated device 800, and thus includes similar components as the integrated device 800. The integrated device 1000 includes the substrate portion 502, the interconnect portion 504, and a redistribution portion 1006. The redistribution portion 1006 is similar to the redistribution portion 706, and thus includes similar or the same components as the redistribution portion 706. The redistribution portion 1006 may be a form of a metallization portion that includes a plurality of interconnects. The redistribution layer (RDL) may be a form of a metallization layer.

The IPD 680 is coupled to the front side of the integrated device 1000. In particular, the IPD 680 is coupled to the redistribution portion 1006 of the integrated device 1000, such that the IPD 680 is located between at least two solder interconnects from the plurality of solder interconnects 260. The IPD 680 includes at least one cavity 682. At least one solder interconnect 260 extends through the at least one cavity 682 of the IPD 680, such that the IPD 680 laterally surrounds the at least one solder interconnect 260. In the example of FIG. 10, the IPD 680 is coupled to the plurality of UBM interconnects 765, through the plurality of passive device solder interconnects 574, in a similar manner as described in FIG. 7.

In some implementations, the IPDs (e.g., 570, 680) may be considered as a passive device interposer (e.g., capacitor interposer layer) for the integrated device.

An integrated device (e.g., 200, 500, 700, 800, 900, 1000) may include a die (e.g., bare die). The integrated device may include a radio frequency (RF) device, an analog device, a passive device, a filter, a capacitor, an inductor, an antenna, a transmitter, a receiver, a surface acoustic wave (SAW) filters, a bulk acoustic wave (BAW) filter, a light emitting diode (LED) integrated device, a silicon (Si) based integrated device, a silicon carbide (SiC) based integrated device, a GaAs based integrated device, a GaN based integrated device, a memory, power management processor, and/or combinations thereof.

As mentioned above, placing the passive device closer to the die may help reduce the voltage droop (e.g., IR droop) to one or more transistors of the integrated device. A reduction in the voltage droop may mean that the transistors receive more voltage, and therefore can operate faster.

Various implementations may have different dimensions for different components of the device, integrated device, and/or IPDs. For example, in some implementations, at least some of the solder interconnects from the plurality of solder interconnects 260 may have a diameter of approximately 100 micrometers (μm), and a height of approximately 70 micrometers (μm). In some implementations, at least some of the solder interconnects from the plurality of passive device solder interconnects 574 may have a diameter of approximately 10 micrometers (μm), and a height of approximately 15 micrometers (μm). Having described various integrated devices coupled to integrated passive devices, a sequence and process for fabricating an integrated device coupled to an integrated passive device will be described below.

### Exemplary Sequence for Fabricating an Integrated Device Coupled to an Integrated Passive Device

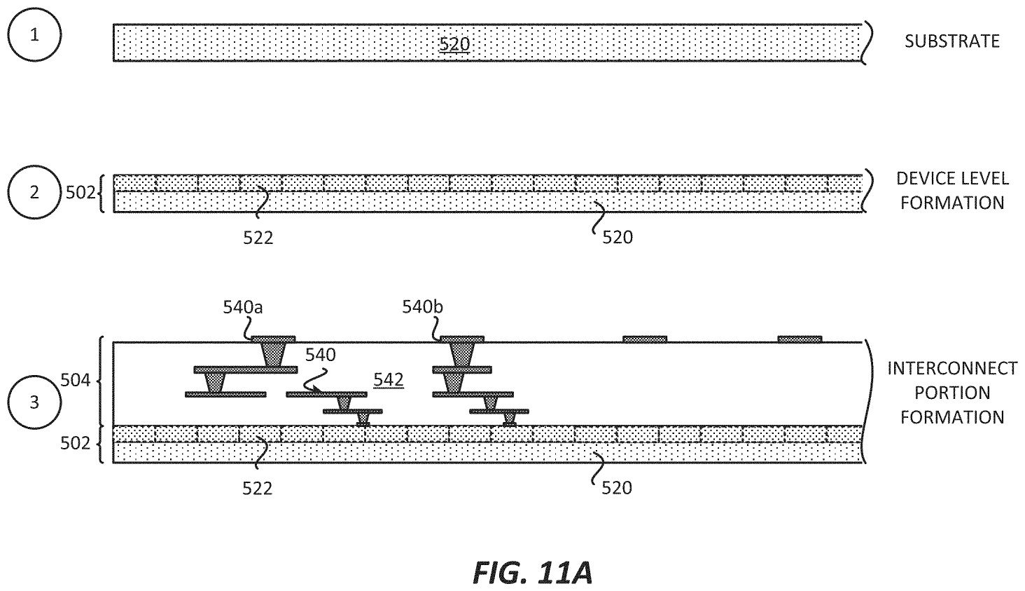

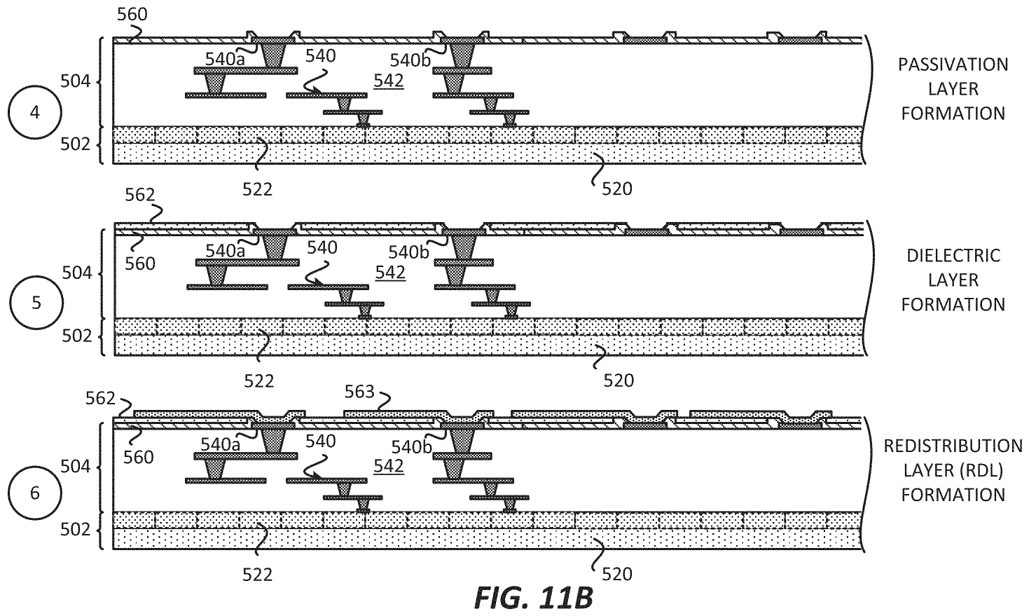

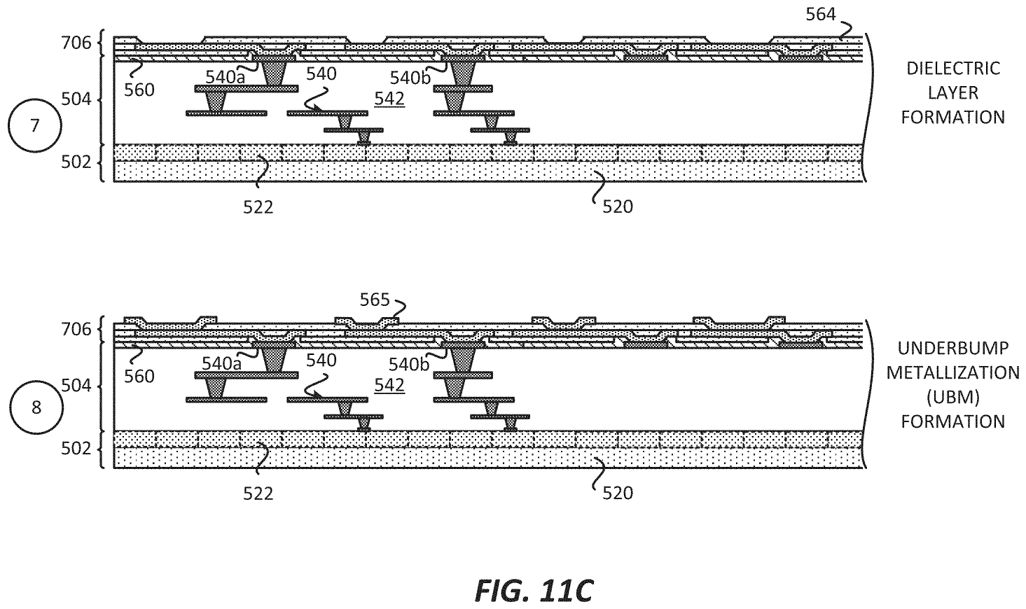

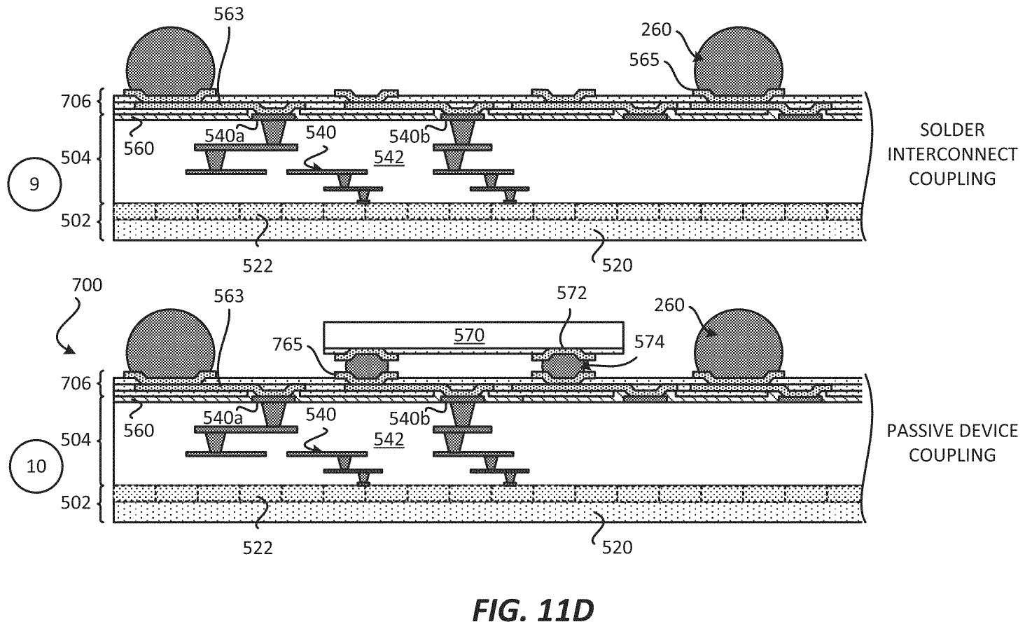

In some implementations, fabricating an integrated device coupled to an integrated passive device includes several processes. FIGS. 11A-11D illustrate an exemplary sequence for providing or fabricating an integrated device coupled to an integrated passive device. In some implementations, the sequence of FIGS. 11A-11D may be used to provide or fabricate the integrated devices of FIGS. 5-10 and/or other integrated devices described in the present disclosure.

It should be noted that the sequence of FIGS. 11A-11D may combine one or more stages in order to simplify and/or clarify the sequence for providing or fabricating an integrated device coupled to an integrated passive device. In some implementations, the order of the processes may be changed or modified. In some implementations, one or more of processes may be replaced or substituted without departing from the spirit of the disclosure.

Stage 1, as shown in FIG. 11A, illustrates a state after a substrate 520 is provided. Different implementations may provide different materials for the substrate 520. In some implementations, the substrate 520 may include silicon (Si). The substrate 520 may be doped or undoped. The substrate 520 may be a semi-insulating substrate. The term “undoped” component as used in the disclosure may mean that the component has no dopant or may include a low doping level of a dopant. The low doping level may be a residual doping level.

Stage 2 illustrates a state after the device level layer is formed over the substrate 520. The device level layer includes a plurality of device level cells 522. Thus, Stage 2 illustrates a state after the plurality of device level cells 522 is formed over the substrate 520. In some implementations, a front end of line (FEOL) process may be used to fabricate the device level layer (e.g., plurality of device level cells 522). One or more of cells from the plurality of device level cells 522 may include one or more transistors. Stage 2 may illustrate a state after a substrate portion 502 is formed.

Stage 3 illustrates a state after the interconnect portion 504 is formed. The interconnect portion 504 may include a plurality of interconnects 540 (located on different metal layers) and at least one dielectric layer 542. In some implementations, a back end of line (BEOL) process may be used to fabricate the interconnect portion 504. A deposition process may be used to form the at least one dielectric layer 542. A depositing process (e.g., plating process) may be used to form the plurality of interconnects 540, which includes interconnect 540a and interconnect 540b. The interconnect portion 504 may be configured to electrically couple one or more transistors.

Stage 4, as shown in FIG. 11B, illustrates a state after a passivation layer 560 is formed over the interconnect portion 504. A deposition process may be used to form the passivation layer 560.

Stage 5 illustrates a state after a dielectric layer 562 is formed over the passivation layer 560. A deposition process may be used to form the dielectric layer 562.

Stage 6 illustrates a state after a redistribution layer (RDL) 563 is formed over the dielectric layer 562. The RDL 563 may include a plurality of redistribution interconnects. The RDL 563 may include redistribution interconnects that include U-shape interconnects or V-shape interconnects. A deposition process (e.g., plating process) may be used to form the RDL 563. Forming the RDL 563 may include forming a seed layer, performing a lithography process, a plating process, a stripping process and/or an etching process.

Stage 7, as shown in FIG. 11C, illustrates a state after a dielectric layer 564 is formed over the RDL 563 and/or the dielectric layer 562. A deposition process may be used to form the dielectric layer 564.

Stage 8 illustrates a state after under bump metallization (UBM) interconnects 565 are formed over the dielectric layer 564 and the RDL 563. The UBM interconnects 565 may include U-shape or V-shape interconnects. A deposition process (e.g., plating process) may be used to form the UBM interconnect 565. The UBM interconnects 565 may be coupled (e.g., electrically coupled) to the RDL 563. Forming the UBM interconnect 565 may include forming a seed layer, performing a lithography process, a plating process, a stripping process and/or an etching process.

Stage 9, as shown in FIG. 11D, illustrates a state after solder interconnects 260 are coupled to the UBM interconnects 565. A reflow solder process may be used to couple the solder interconnects 260 to the UBM interconnects 565.

Stage 10 illustrates a state after the IPD 570 is coupled to the front side of the integrated device 500. In particular, the IPD 570 is coupled to the redistribution portion 706 of the integrated device 700, such that the IPD 570 is located laterally between at least two solder interconnects from the plurality of solder interconnects 260. In this example, the IPD 570 is coupled to the UBM interconnects 765, through the plurality of passive device solder interconnects 574. The plurality of UBM interconnects 572 is coupled to the plurality of passive device solder interconnects 574. In some implementations, a first UBM interconnect from the IPD 570 is configured for power, and a second UBM interconnect from the IPD 570 is configured for ground.

### Exemplary Flow Diagram of a Method for Fabricating an Integrated Device Coupled to an Integrated Passive Device

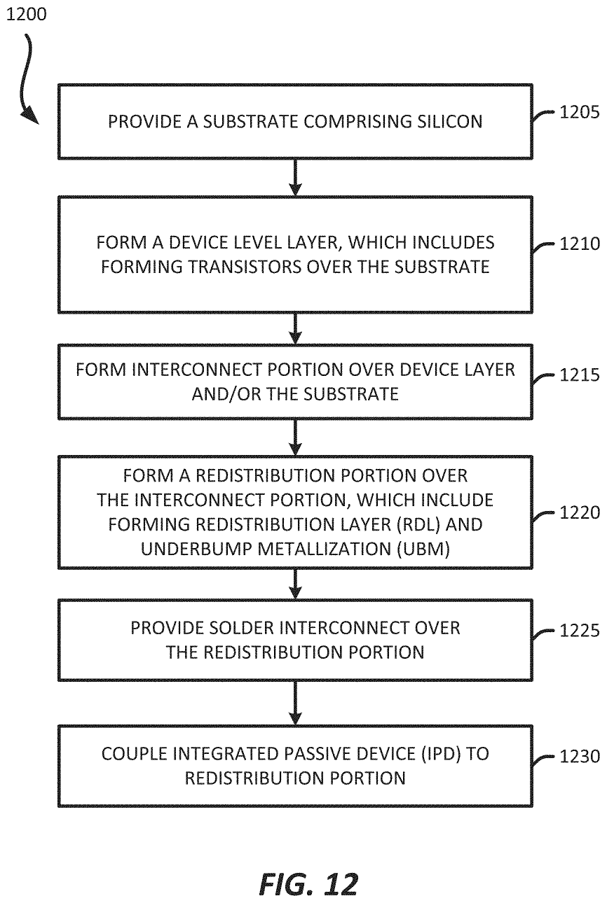

In some implementations, providing an integrated device coupled to an integrated passive device includes several processes. FIG. 12 illustrates an exemplary flow diagram of a method 1200 for providing or fabricating an integrated device coupled to an integrated passive device. In some implementations, the method 1200 of FIG. 12 may be used to provide or fabricate the integrated devices of FIGS. 5-10 and/or other integrated devices described in the present disclosure.

It should be noted that the method of FIG. 12 may combine one or more processes in order to simplify and/or clarify the method for providing or fabricating an integrated device coupled to an integrated passive device. In some implementations, the order of the processes may be changed or modified.

The method provides (at 1205) a substrate (e.g., 520). The substrate 520 may include silicon. Stage 1 of FIG. 11A illustrates an example of providing a substrate.

The method forms (at 1210) a device level layer, which includes forming transistors over the substrate. The transistors may be formed in device level cells (e.g., 522) of the substrate 520. In some implementations, a front end of line (FEOL) process may be used to fabricate the device level layer (e.g., plurality of device level cells 522). Stage 2 of FIG. 11A illustrates an example of forming a device level layer that includes transistors.

The method forms (at 1215) an interconnect portion (e.g., 504) over the substrate and the device level layer. Forming the interconnect portion includes forming a plurality of interconnects (e.g., 540) (located on different metal layers) and at least one dielectric layer (e.g., 542). In some implementations, a back end of line (BEOL) process may be used to fabricate the interconnect portion 504. A deposition process may be used to form the at least one dielectric layer 542. A depositing process (e.g., plating process) may be used to form the plurality of interconnects 540. Stage 3 of FIG. 11A illustrates an example of forming an interconnect portion.

The method forms (at 1220) a redistribution portion (e.g., 706) over the interconnect portion. A redistribution portion may be a type of a metallization portion that includes at least one metallization layer (e.g., RDL). Forming a redistribution portion may include forming a passivation layer (e.g., 560), an RDL 563, a UBM interconnect 565, and at least one dielectric layer (e.g., 562, 564, 566). A deposition process may be used to form the dielectric layer(s). A deposition process (e.g., a plating process) may be used to form the RDL 563 and the UBM interconnect 565. Stages 4-8 of FIGS. 11B-11C, illustrate an example of forming a redistribution portion.

The method couples (at 1225) a plurality of solder interconnects (e.g., 260) to the front side of an integrated device. The plurality of solder interconnects 260 may be coupled to the redistribution portion 706. The plurality of solder interconnects may be coupled to the UBM interconnect 565. A reflow solder process may be used to couple the solder interconnects 260 to the UBM interconnects 565. Stage 9 of FIG. 11D, illustrates an example of coupling a plurality of solder interconnects to the UBM interconnects.

The method couples (at 1230) at least one IPD (e.g., 570, 680) to the front side of an integrated device. The at least one IPD may be coupled to the redistribution portion (e.g., 506, 606, 706, 806, 906, 1006) of the integrated device. The at least one IPD may be coupled (through a plurality of passive device solder interconnects) to the UBM interconnects, and/or the RDLs of the portion redistribution (e.g., 506, 606, 706). Stage 10 of FIG. 11D is an example that illustrates a state after the IPD 570 is coupled to the front side of the integrated device 700. In particular, the IPD 570 is coupled to the redistribution portion 706 of the integrated device 700, such that the IPD 570 is located between at least two solder interconnects from the plurality of solder interconnects 260. In this example, the IPD 570 is coupled to the UBM interconnects 765, through the plurality of passive device solder interconnects 574. The plurality of UBM interconnects 572 is coupled to the plurality of passive device solder interconnects 574. In some implementations, a first UBM interconnect (e.g., first terminal) from the IPD 570 is configured for power, and a second UBM interconnect (e.g., second terminal) from the IPD 570 is configured for ground.

Different implementations may couple different IPDs to an integrated device. Below are examples of how IPDs may be coupled to an integrated device.

### Exemplary Integrated Device Coupled to Integrated Passive Device (IPD)

FIG. 13 illustrates an example of a device 1300 that includes an integrated device 1302, an integrated passive device (IPD) 204, and an IPD 205. The integrated device 1302 may include a front side and a back side. The integrated device 1302 includes a die (e.g., bare semiconductor die) that has a front side and back side. The integrated device 1302 may include the integrated device 500, which includes the die 501 and the redistribution portion 506. A plurality of pillar interconnects 1360 is coupled to the front side of the integrated device 1302. The integrated device 1302 is coupled to a substrate 1390 (e.g., package substrate) through the plurality of pillar interconnects 1360 (e.g., copper pillars). The IPD 204 and the IPD 205 are coupled to the front side of the integrated device 1302 (e.g., coupled to a front side of a die). The IPD 204 is coupled to the front side of the integrated device 1302 through a plurality of solder interconnects 240. The solder interconnects 240 may be located between an interconnect 1342 (e.g., pad) of the IPD 204 and an interconnect 1340 (e.g., pad) of the integrated device 1302. The IPD 205 is coupled to the front side of the integrated device 1302 through a plurality of solder interconnects 250. The solder interconnects 250 may be located between an interconnect 1352 (e.g., pad) of the IPD 205 and an interconnect 1350 (e.g., pad) of the integrated device 1302. The IPD 204 and the IPD 205 are located between the integrated device 1302 and the substrate 1390. FIG. 13 also illustrates that the IPD 204 and the IPD 205 are each located laterally between two pillar interconnects from the plurality of pillar interconnects 1360. The IPD 205 may laterally surround at least one pillar interconnect from the plurality of pillar interconnects 1360. For example, the IPD 205 may include a cavity through which at pillar interconnect may extend through.

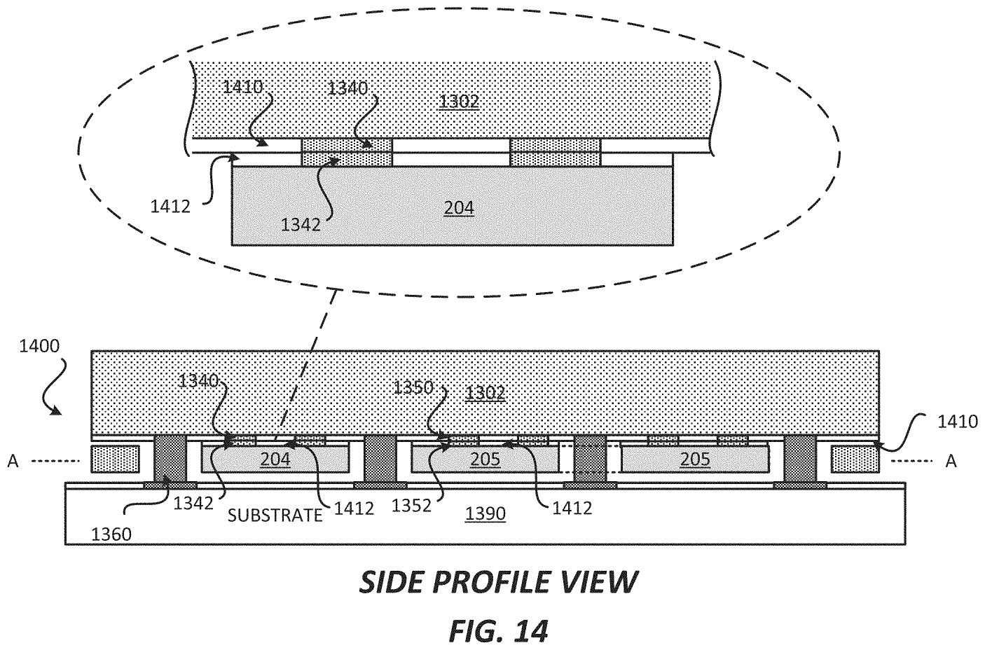

FIG. 14 illustrates an example of a device 1400 that includes an integrated device 1302, the IPD 204, and the IPD 205. The integrated device 1302 may include a front side and a back side. The integrated device 1302 includes a die (e.g., bare semiconductor die) that has a front side and back side. The integrated device 1302 may include the integrated device 500, which includes the die 501 and the redistribution portion 506. The device 1400 is similar to the device 1300 of FIG. 13, and thus includes similar components as the device 1300. FIG. 14 illustrates that the IPD 204 and the IPD 205 are coupled to the integrated device 1302 through oxide to oxide coupling, which may bypass the use of solder interconnects. The integrated device 1302 includes an oxide layer 1410 (e.g., die oxide layer). Each of the IPD 204 and the IPD 205 includes an oxide layer 1412 (e.g., IPD oxide layer). The oxide layer 1410 of the integrated device 1302 and the oxide layer of the IPD 204 and the 205 may allow the IPD 204 and the IPD 205 to be coupled to the integrated device 1302. The interconnect 1342 (e.g., pad) of the IPD 204 is coupled to the interconnect 1340 (e.g., pad) of the integrated device 1302, without the need of a solder interconnect. The interconnect 1352 (e.g., pad) of the IPD 205 is coupled to the interconnect 1350 (e.g., pad) of the integrated device 1302, without the need of a solder interconnect. The plurality of solder interconnects 240 and/or the plurality of solder interconnects 250 may be similar to the plurality of passive device solder interconnects 574, including having similar composition and/or sizes. FIG. 14 may illustrate an example of copper to copper hybrid bonding.

### Exemplary Integrated Device Coupled to Integrated Passive Device (IPD)

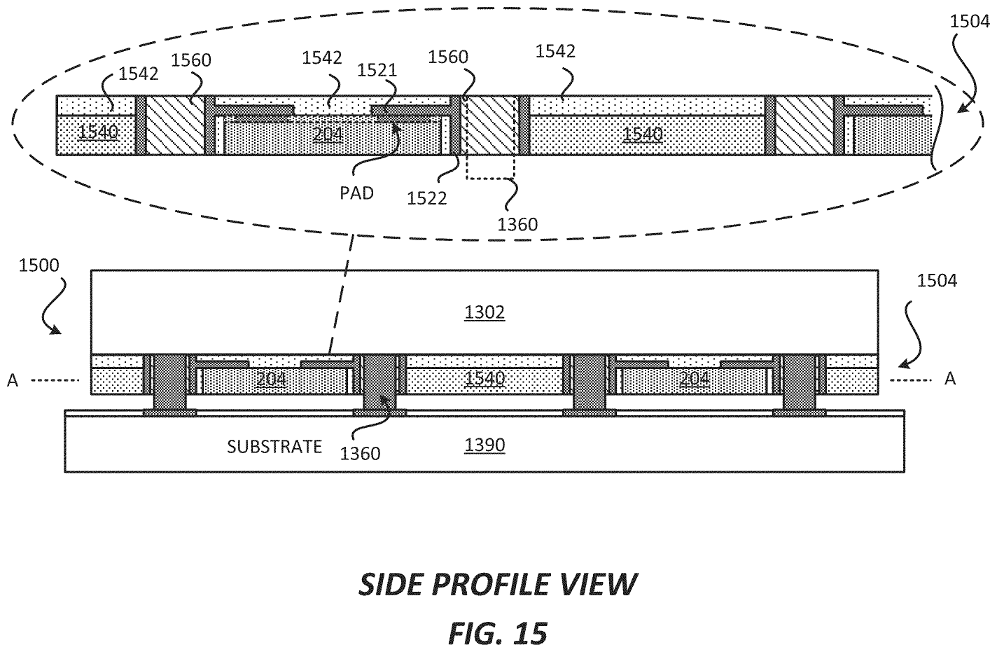

FIG. 15 illustrates an example of a device 1500 that includes the integrated device 1302, and a passive device interposer 1504. The integrated device 1302 may include a front side and a back side. The integrated device 1302 includes a die (e.g., bare semiconductor die) that has a front side and back side. The integrated device 1302 may include the integrated device 500, which includes the die 501 and the redistribution portion 506. A plurality of pillar interconnects 1360 is coupled to the front side of the integrated device 1302 (e.g., front side of the die). The integrated device 1302 is coupled to a substrate 1390 (e.g., package substrate) through the plurality of pillar interconnects 1360 (e.g., copper pillars).

The passive device interposer 1504 is coupled to the front side of the integrated device 1302 (e.g., coupled to a front side of the die), such that the passive device interposer 1504 is located between the integrated device 1302 and the substrate 1390. The passive device interposer 1504 may include the IPD 204, an encapsulation layer 1540, a dielectric layer 1542, an interconnect 1521, an interconnect 1522, and a solder interconnect 1560. The interconnect 1521 may include a pad (and/or trace) coupled to the IPD 204. The interconnect 1522 may include a via coupled to the interconnect 1521. The interconnect 1522 may extend through a cavity in the passive device interposer 1504. The interconnect 1522 may be formed on a wall of the encapsulation layer 1540 and/or the dielectric layer 1542. The interconnect 1521 and the interconnect 1522 may be considered part of the same interconnect. The encapsulation layer 1540 may include a mold, a resin, an epoxy and/or polymer. The encapsulation layer 1540 may be means for encapsulation. The solder interconnect 1560 may be located in a cavity of the passive device interposer 1504.

The IPD 204 may be configured to be electrically coupled to the integrated device 1302 through the interconnect 1521 (e.g., pad), the interconnect 1522 (e.g., via), the solder interconnect 1560, and the pillar interconnect 1360. In some implementations, a first set of (i) the interconnect 1521 (e.g., pad), (ii) the interconnect 1522 (e.g., via), (iii) the solder interconnect 1560, and (iv) the pillar interconnect 1360 coupled to the IPD 204 and the integrated device 1302, may be configured for power. Thus, a first terminal from the IPD 204 may be configured for power. In some implementations, a second set of (i) the interconnect 1521 (e.g., pad), (ii) the interconnect 1522 (e.g., via), (iii) the solder interconnect 1560, and (iv) the pillar interconnect 1360 coupled to the IPD 204 and the integrated device 1302, may be configured for ground. Thus, a second terminal from the IPD 204 may be configured for ground.

The passive device interposer 1504 may have a lateral size (or footprint) that is approximately the same as the lateral size of the integrated device 1302. However, different implementations may use a passive device interposer 1504 with different lateral sizes and/or shapes.

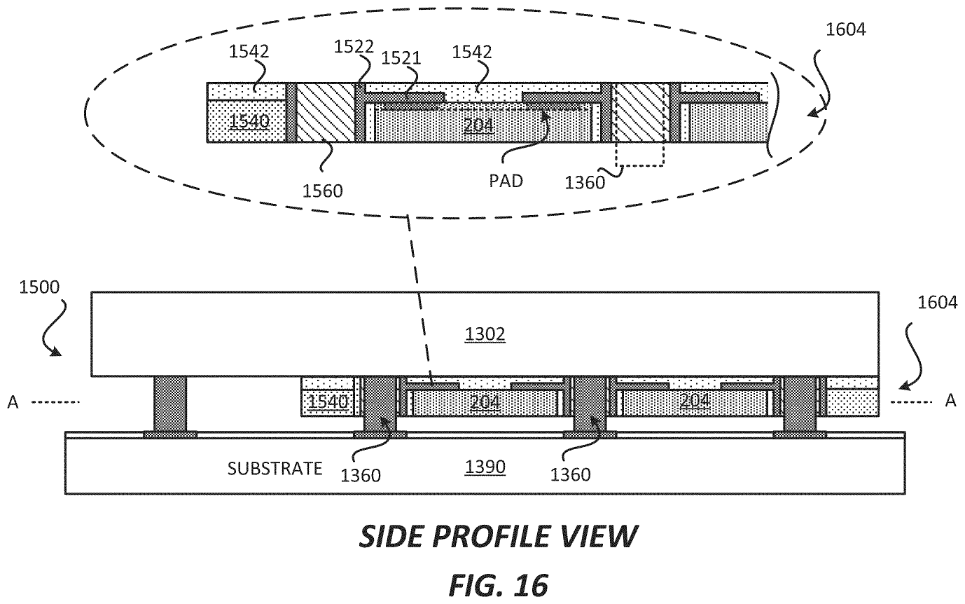

FIG. 16 illustrates a passive device interposer 1604 that is similar to the passive device interposer 1504. The passive device interposer 1604 includes similar components as the passive device interposer 1506, and may be coupled to the integrated device 1302 in a similar manner as described in FIG. 15. The passive device interposer 1604 has a smaller lateral size (or footprint) than the lateral size of the integrated device 1302 and/or a different shape than the shape of the passive device interposer 1504.

Different implementations may use different numbers of IPDs, and may position the IPDs in different locations. The IPDs of the passive device interposer (e.g., 1504, 1604) may have different sizes and/or shapes. The passive device interposer and/or the IPDs of FIGS. 15 and 16 may be a means for passive operation. The use of the IPD(s) between pillar interconnects and/or near the integrated device helps reduce the voltage droop (e.g., IR droop) to a transistor, thus more voltage can be applied to a transistor, resulting is better transistor speeds and improved circuit timing.

Various implementations may have different dimensions for different components of the device, integrated device, passive device interposer and/or IPDs. For example, in some implementations, at least some of the pillar interconnects from the plurality of pillar interconnects 1360 may have a diameter of approximately 50 micrometers (μm), and a height of approximately 70 micrometers (μm). The shape and/or size of the IPDs (e.g., 204, 205) may vary. In some implementations, an IPD may have footprint that is approximately 150 micrometers (μm)×100 micrometers (μm), or less.

### Exemplary Sequence for Fabricating a Passive Device Interposer

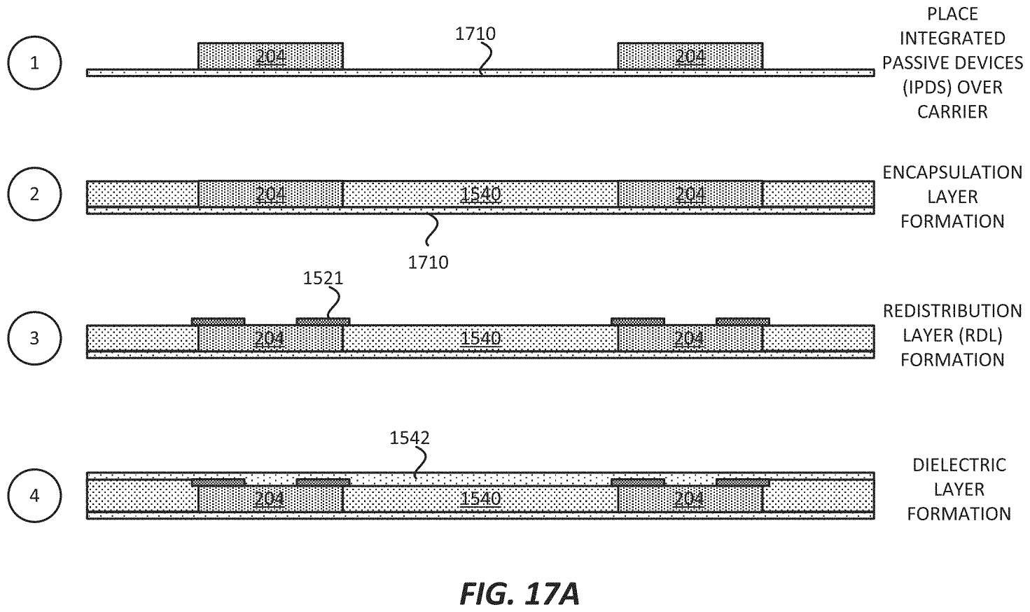

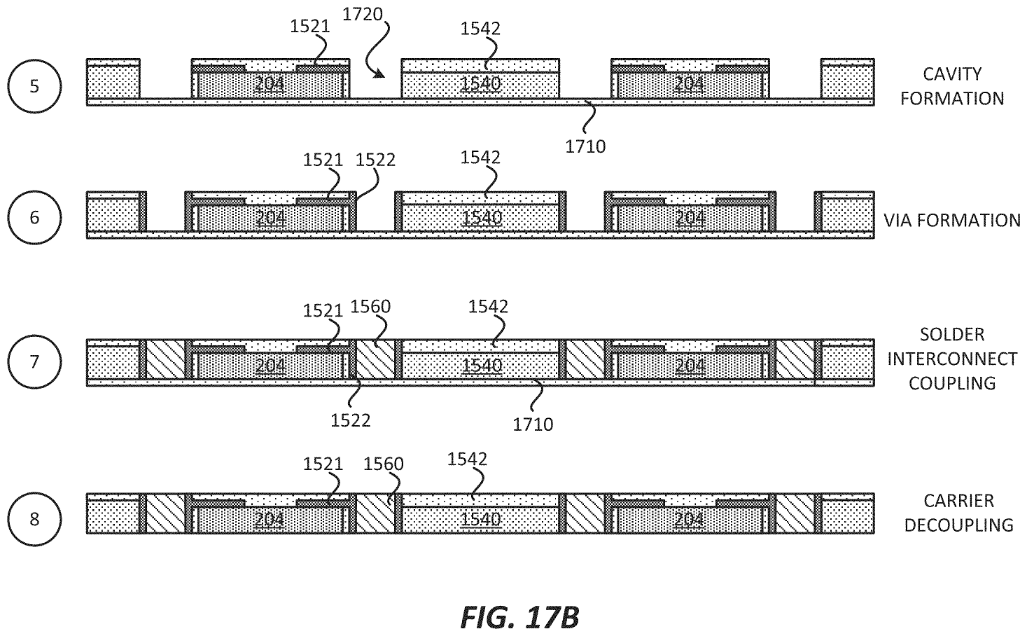

In some implementations, fabricating a passive device interposer includes several processes. FIGS. 17A-17B illustrate an exemplary sequence for providing or fabricating a passive device interposer. In some implementations, the sequence of FIGS. 17A-17B may be used to provide or fabricate the passive device interposer of FIG. 15 and/or other passive device interposers described in the present disclosure.

It should be noted that the sequence of FIGS. 17A-17B may combine one or more stages in order to simplify and/or clarify the sequence for providing or fabricating a passive device interposer. In some implementations, the order of the processes may be changed or modified. In some implementations, one or more of processes may be replaced or substituted without departing from the spirit of the disclosure.

Stage 1, as shown in FIG. 17A, illustrates a state after integrated passive devices (IPDs) 204 are placed over a carrier 1710. The carrier 1710 may include a substrate and/or wafer. The IPDs 204 may be positioned over the carrier 1710 using a pick and place process.

Stage 2 illustrates a state after the encapsulation layer 1540 is disposed (e.g., formed) over the carrier 1710 and the IPDs 204. The process of forming and/or disposing the encapsulation layer 1540 may include using a compression and transfer molding process, a sheet molding process, or a liquid molding process. The encapsulation layer 1540 may include a mold, a resin, an epoxy and/or polymer.

Stage 3 illustrates a state after interconnects 1521 are formed over the IPDs 204. The interconnects 1521 may define pads for the IPDs 204. In some implementations, the interconnects 1521 may be formed over pads of the IPDs 204. In some implementations, the interconnects 1521 may include redistribution interconnects, which are formed using a redistribution process (such as described in FIGS. 11A-11D, for example).

Stage 4 illustrates a state after a dielectric layer 1542 is formed over the encapsulation layer 1540, the IPDs 204 and the interconnects 1521. A deposition process may be used to form the dielectric layer 1542.

Stage 5, as shown in FIG. 17B, illustrates a state after cavities 1720 are formed over the encapsulation layer 1540 and the dielectric layer 1542. An etching process or a laser process may be used to form the cavities 1720. In some implementations, the cavities 1720 does not extend through the carrier 1710. In some implementations, the cavities 1720 may extend through the carrier 1710.

Stage 6 illustrates a state after the interconnect 1522 are formed over the walls of the cavities 1720. The interconnect 1522 may be vias in the cavities 1720. A plating process may be used to form the interconnect 1522. The interconnect 1522 is formed such that the interconnect 1522 is coupled to the interconnect 1521. The interconnect 1522 may considered part of the interconnect 1521, and vice versa. The interconnect 1522 may be formed over the encapsulation layer 1540 and the dielectric layer 1542.

Stage 7 illustrates a state after the solder interconnects 1560 are disposed in the cavities 1720. The solder interconnects 1560 may include solder paste. Stage 7 may illustrate a passive device interposer 1504 that includes a carrier 1710.

Stage 8 illustrates a state after the carrier 1710 is decoupled from the encapsulation layer 1540 and the IPDs 204, leaving a passive device interposer 1504 that does not include a carrier 1710.

### Exemplary Flow Diagram of a Method for Fabricating a Passive Device Interposer

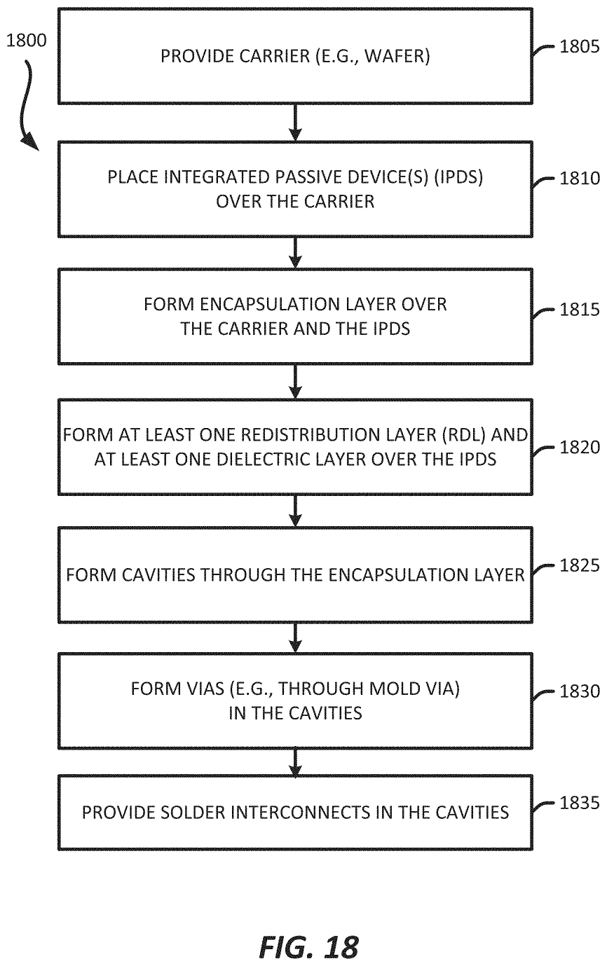

In some implementations, providing a passive device interposer includes several processes. FIG. 18 illustrates an exemplary flow diagram of a method 1800 for providing or fabricating a passive device interposer. In some implementations, the method 1800 of FIG. 18 may be used to provide or fabricate the passive device interposer of FIG. 15 and/or other passive device interposer described in the present disclosure.

It should be noted that the method of FIG. 18 may combine one or more processes in order to simplify and/or clarify the method for providing or fabricating a passive device interposer. In some implementations, the order of the processes may be changed or modified.

The method provides (at 1805) a carrier (e.g., 1710). The carrier may include a substrate and/or wafer. Stage 1 of FIG. 17A illustrates an example of providing a carrier.

The method places (at 1810) IPDs over the carrier. A pick and place may be used to position the IPDs over the carrier. An IPD may include a die. Stage 1 of FIG. 17A illustrates an example of IPDs placed over a carrier.

The method forms (at 1815) an encapsulation layer (e.g., 1540) over the carrier 1710 and the IPDs 204. The process of forming and/or disposing the encapsulation layer 1540 may include using a compression and transfer molding process, a sheet molding process, or a liquid molding process. The encapsulation layer 1540 may include a mold, a resin, an epoxy and/or polymer. Stage 2 of FIG. 17A illustrates an example of forming an encapsulation layer.

The method forms (at 1820) interconnects (e.g., 1521) over the IPDs (e.g., 204). The interconnects 1521 may define pads for the IPDs 204. In some implementations, the interconnects 1521 may be formed over pads of the IPDs 204. In some implementations, the interconnects 1521 may include redistribution interconnects, which are formed using a redistribution process (such as described in FIGS. 11A-11D, for example). Stage 3 of FIG. 17A illustrates an example of forming interconnects formed over IPDs. The method may further form (at 1820) a dielectric layer (e.g., 1542) over the encapsulation layer 1540, the interconnects 1521 and the IPDs 204. A deposition process may be used to form the dielectric layer. Stage 4 of FIG. 17A illustrates an example of forming a dielectric layer.

The method forms (at 1825) cavities (e.g., 1720) in the encapsulation layer 1540 and the dielectric layer 1542. Stage 4 illustrates a state after a dielectric layer 1542 is formed over the encapsulation layer 1540, the IPDs 204 and the interconnects 1521. A deposition process may be used to form the dielectric layer 1542. An etching process or a laser process may be used to form the cavities 1720. In some implementations, the cavities 1720 does not extend through the carrier 1710. In some implementations, the cavities 1720 may extend through the carrier 1710. Stage 5 of FIG. 17B illustrates an example of forming cavities over the encapsulation layer 1540.

The method forms (at 1830) vias in the cavities 1720. The vias may be the interconnect 1522. A plating process may be used to form the interconnect 1522. The interconnect 1522 is formed such that the interconnect 1522 is coupled to the interconnect 1521. The interconnect 1522 may be formed over the encapsulation layer 1540 and the dielectric layer 1542. Stage 6 of FIG. 17B illustrates an example of forming vias.

The method provides (at 1835) solder interconnects (e.g., 1560) in the cavities (e.g., 1720). The solder interconnects 1560 may include solder paste. Stage 7 illustrates an example of providing solder interconnects.

In some implementations, the method may decouple the carrier (at 1710) from the encapsulation layer 1540 and the IPDs 204, leaving a passive device interposer 1504 that does not include a carrier 1710. Stage 8 illustrates an example after a carrier is decoupled from an encapsulation layer and the IPDs.

### Exemplary Sequence for Fabricating an Integrated Device Coupled to a Passive Device Interposer

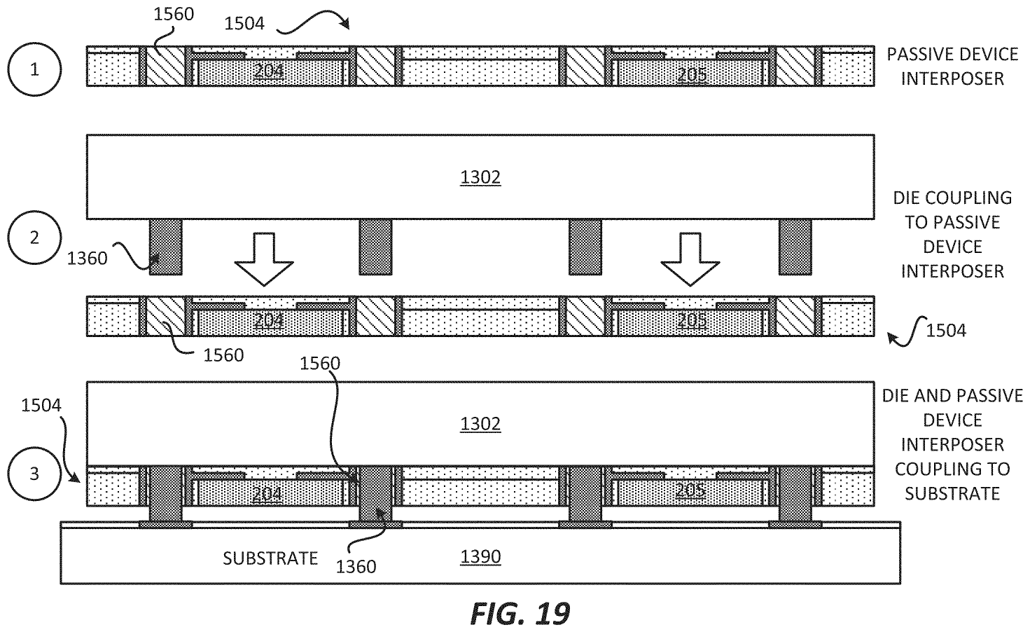

In some implementations, fabricating an integrated device coupled to a passive device interposer includes several processes. FIG. 19 illustrates an exemplary sequence for providing or fabricating an integrated device coupled to a passive device interposer. In some implementations, the sequence of FIG. 19 may be used to provide or fabricate the integrated device with the interposer of FIG. 15 and/or other integrated devices with interposers described in the present disclosure.

It should be noted that the sequence of FIG. 19 may combine one or more stages in order to simplify and/or clarify the sequence for providing or fabricating an integrated device coupled to a passive device interposer. In some implementations, the order of the processes may be changed or modified. In some implementations, one or more of processes may be replaced or substituted without departing from the spirit of the disclosure.

Stage 1, as shown in FIG. 19, illustrates a state after a passive device interposer 1504 is provided. The passive device interposer 1504 may be fabricated using a process described in FIGS. 17A-17B. In some implementations, the passive device interposer may be the passive device interposer 1604.

Stage 2 illustrates an integrated device 1302 comprising a plurality of pillar interconnects 1360 being coupled to the passive device interposer 1504, such that the plurality of pillar interconnects 1360 extends through at least one of the solder interconnects 1560 located in the cavities of the passive device interposer 1504.

Stage 3 illustrates the integrated device 1302 and the passive device interposer 1504 coupled to the substrate 1390. Stage 3 may illustrate the device 1500 of FIG. 15. The plurality of pillar interconnects 1360 extends through the cavities and solder interconnects 1560 of the passive device interposer 1504, to couple to the substrate 1390. The plurality of pillar interconnects 1360 may be coupled to interconnects of the substrate 1390.

### Exemplary Flow Diagram of a Method for Fabricating an Integrated Device Coupled to a Passive Device Interposer

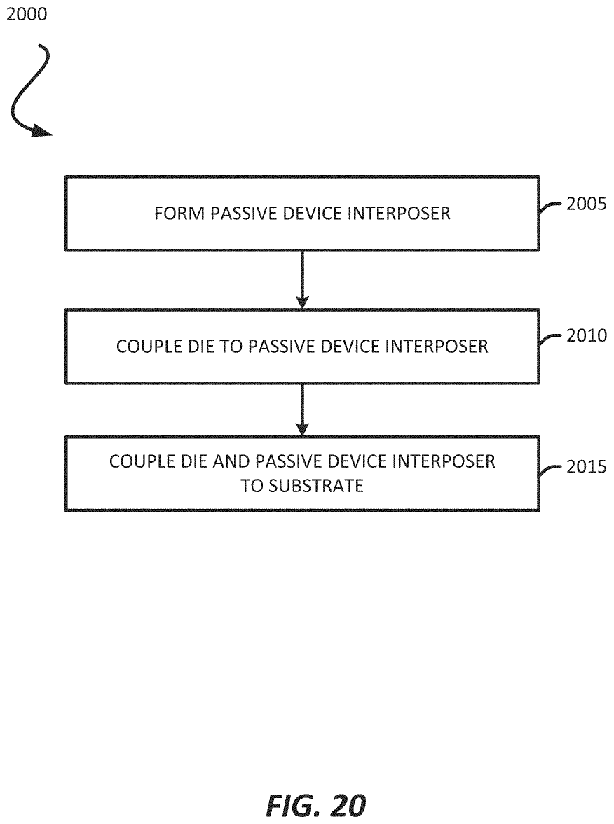

In some implementations, providing an integrated device coupled to a passive device interposer includes several processes. FIG. 20 illustrates an exemplary flow diagram of a method 2000 for providing or fabricating an integrated device coupled to a passive device interposer. In some implementations, the method 2000 of FIG. 20 may be used to provide or fabricate the integrated device coupled to a passive device interposer of FIG. 15 and/or other integrated devices coupled to a passive device interposer described in the present disclosure.

It should be noted that the method of FIG. 20 may combine one or more processes in order to simplify and/or clarify the method for providing or fabricating an integrated device coupled to a passive device interposer. In some implementations, the order of the processes may be changed or modified.

The method provides (at 2005) a passive device interposer (e.g., 1504) that includes IPDs. The passive device interposer may be fabricated using the process described in FIGS. 17A-17B. Stage 1 of FIG. 19, illustrates an example of providing a passive device interposer.

The method couples (at 2010) an integrated device (e.g., 1302) comprising a plurality of pillar interconnects (e.g., 1360) to the passive device interposer 1504, such that the plurality of pillar interconnects 1360 extends through at least one of the solder interconnects 1560 located in the cavities of the passive device interposer 1504. Stage 2 of FIG. 19, illustrates an example of an integrated device coupling to a passive device interposer.

The method couples (at 2015) the integrated device and the passive device interposer to a substrate. The integrated device and the passive device interposer may be coupled to the substrate such that the plurality of pillar interconnects 1360 extends through the cavities and solder interconnects 1560 of the passive device interposer 1504, to couple to the substrate 1390. The plurality of pillar interconnects 1360 may be coupled to interconnects of the substrate 1390. Stage 3 of FIG. 19 illustrates an example of an integrated device and a passive device interposer coupled to a substrate.

### Exemplary Integrated Device Coupled to Integrated Passive Device (IPD)

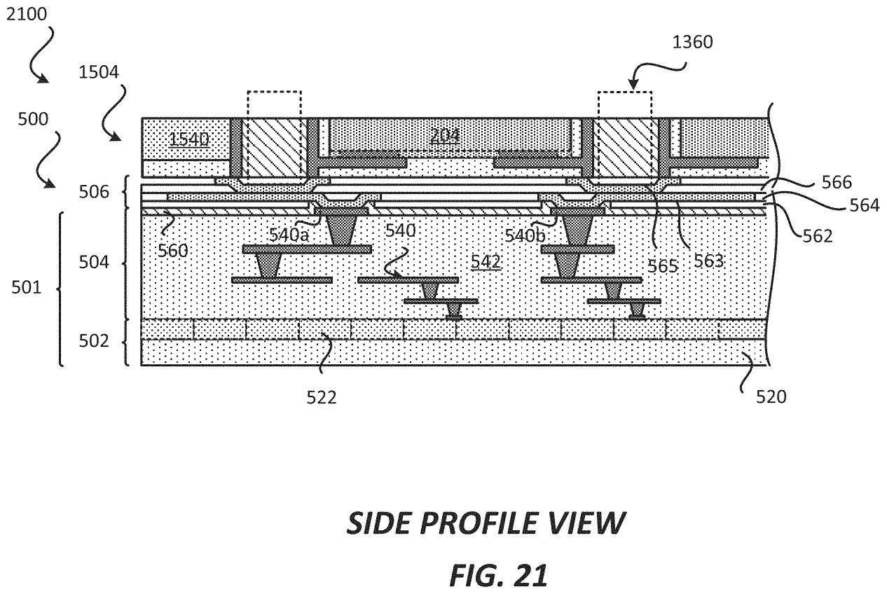

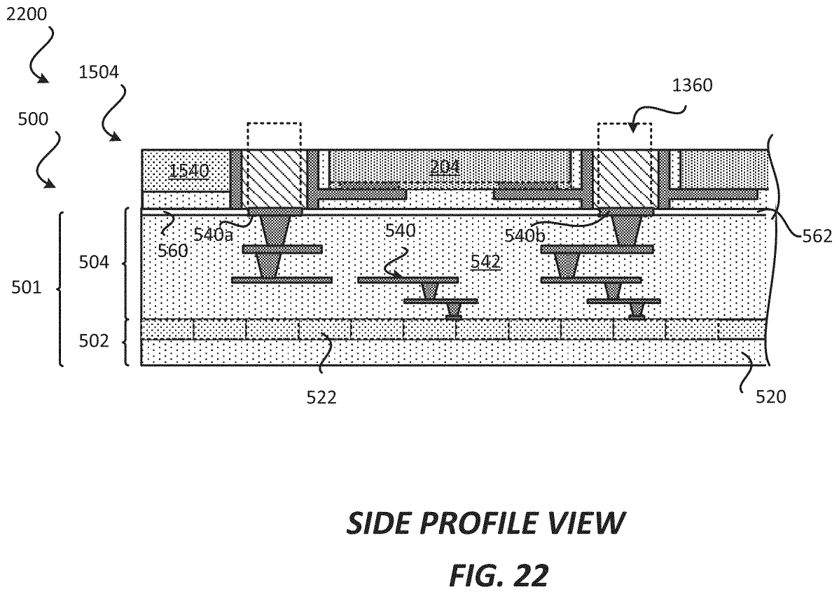

FIGS. 21 and 22 illustrate examples of devices that include an integrated device and a passive device interposer. FIG. 21 illustrates an example of a device 2100 that includes an integrated device 500 and a passive device interposer 1504. The integrated device 500 may include a front side and a back side. The integrated device 500 may include the die 501 and the redistribution portion 506. A plurality of pillar interconnects 1360 is coupled to the front side of the integrated device 500. In particular, the plurality of pillar interconnects 1360 is coupled to the redistribution portion 506. The integrated device 500 may be coupled to a substrate (e.g., package substrate) or a board, through the plurality of pillar interconnects 1360 (e.g., copper pillars). The integrated device 500 may be a wafer level package (WLP). In the example of FIG. 21, the plurality of pillar interconnects 1360 is coupled to the UBM interconnects 565 of the redistribution portion 506.

In some implementations, the redistribution portion 506 may be optional, and the plurality of pillar interconnects 1360 may be coupled to interconnects of the die 501. FIG. 22 illustrates an example of the passive device interposer 1504 and the plurality of pillar interconnects 1360 that may be coupled to the die 501 (e.g., front side of the die). For example, as shown in FIG. 22, at least one of the pillar interconnects from the plurality of pillar interconnects 1360 may be coupled to the interconnect 540a (e.g., pad). In some implementations, the passive device interposer 1604 may be coupled to the integrated device 500 (which may or may not include a redistribution portion (e.g., metallization portion)).

In some implementations, the integrated device 500 may include an oxide layer (e.g., 1410) over the die 501 or over the redistribution portion 506 (e.g., over the dielectric layer 566). The device 2100 of FIG. 21 and the device 2200 of FIG. 22 may be more detailed examples of the device 1500 of FIG. 15 and/or the device 1600 of FIG. 16. In some implementations, the integrated device 500 that includes the die 501 (with or without the redistribution portion 506) may be an example of the integrated device 1302, as shown in FIGS. 13 and 14.

It is noted that the disclosure illustrates a redistribution portion (e.g., 506) that includes one RDL. However, different implementations may include a redistribution portion that includes several RDLs coupled to each other. In some implementations, the UBM interconnects may be coupled to the top most RDL (e.g., metallization layer) of the redistribution portion (e.g., metallization portion)

### Exemplary Electronic Devices

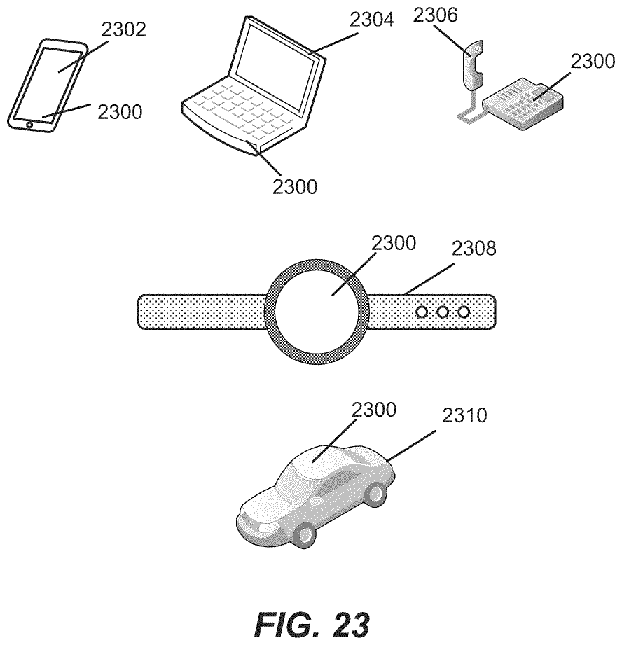

FIG. 23 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 2302, a laptop computer device 2304, a fixed location terminal device 2306, a wearable device 2308, or automotive vehicle 2310 may include a device 2300 as described herein. The device 2300 may be, for example, any of the devices and/or integrated circuit (IC) packages described herein. The devices 2302, 2304, 2306 and 2308 and the vehicle 2310 illustrated in FIG. 23 are merely exemplary. Other electronic devices may also feature the device 2300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 2-10, 11A-11D, 12-16, 17A-17B, and 18-23 may be rearranged and/or combined into a single component, process, feature or function or embodied in several components, processes, or functions. Additional elements, components, processes, and/or functions may also be added without departing from the disclosure. It should also be noted FIGS. 2-10, 11A-11D, 12-16, 17A-17B, and 18-23 and its corresponding description in the present disclosure is not limited to dies and/or ICs. In some implementations, FIGS. 2-2-10, 11A-11D, 12-16, 17A-17B, and 18-23 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
an integrated device comprising a metallization portion, wherein the metallization portion comprises:
at least one metallization layer; and
a plurality of under bump metallization interconnects;
a plurality of solder interconnects coupled to the metallization portion; and
an integrated passive device coupled to the metallization portion, wherein the integrated passive device is located laterally between at least two solder interconnects from the plurality of solder interconnects.

2. The device of claim 1, wherein the integrated passive device is coupled to the at least one metallization layer of the metallization portion.

3. The device of claim 1, wherein the integrated passive device is coupled to the plurality of under bump metallization interconnects of the metallization portion.

4. The device of claim 1,
wherein the integrated passive device includes a plurality of integrated passive device under bump metallization interconnects, and
wherein the plurality of integrated passive device under bump metallization interconnects is coupled to the at least one metallization layer of the metallization portion through a plurality of first solder interconnects.

5. The device of claim 1,
wherein the integrated passive device includes a plurality of integrated passive device under bump metallization interconnects, and
wherein the plurality of integrated passive device under bump metallization interconnects is coupled to the plurality of under bump metallization interconnects of the metallization portion through a plurality of first solder interconnects.

6. The device of claim 1, wherein the integrated passive device includes a die configured to operate as a passive device.

7. The device of claim 1, wherein the integrated passive device includes a cavity through which a solder interconnect extends through.

8. The device of claim 1, wherein the integrated passive device has a lateral size that is approximately the same or less, than the lateral size of the die.

9. The device of claim 1, wherein a first terminal of the integrated passive device is configured to couple to power and a second terminal of the integrated passive device is configured to couple to ground.

10. The device of claim 1,
wherein the metallization portion includes a redistribution portion, and
wherein the at least one metallization layer includes at least one redistribution layer.

11. The device of claim 10, wherein the at least one redistribution layer includes a plurality of redistribution interconnects.

12. The device of claim 11, wherein the plurality of redistribution interconnects is coupled to the plurality of under bump metallization interconnects.

13. The device of claim 1, wherein the at least one metallization layer includes at least one U-shape interconnect and/or V-shape interconnect.

14. The device of claim 1, wherein the device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

15. A device comprising:
an integrated device;
a plurality of pillar interconnects coupled to the integrated device; and
an integrated passive device coupled to the integrated device, wherein the integrated passive device is located laterally between at least two pillar interconnects from the plurality of pillar interconnects.

16. The device of claim 15, wherein the integrated passive device is coupled to the integrated device through a plurality of first solder interconnects.

17. The device of claim 15, wherein the integrated passive device includes a die configured to operate as a passive device.

18. The device of claim 15, wherein the integrated passive device includes a cavity through which a pillar interconnect travels through.

19. The device of claim 15, wherein the integrated passive device is coupled to the die through a plurality of first solder interconnects.

20. The device of claim 15,
wherein the integrated device includes a die oxide layer,
wherein the integrated passive device includes an integrated passive device oxide layer, and
wherein the integrated passive device is coupled to the integrated device such that the integrated passive device oxide layer is coupled to the die oxide layer.

21. The device of claim 15, wherein the integrated device includes a die having a front side and back side.

22. A device comprising:
an integrated device;
a plurality of pillar interconnects coupled to the integrated device; and
a passive device interposer coupled to the integrated device and the plurality of pillar interconnects, wherein the passive device interposer comprises:
an integrated passive device;
an encapsulation layer;
an interconnect coupled to the integrated passive device;
a solder interconnect coupled the interconnect and to at least one pillar interconnect from the plurality of pillar interconnects.

23. The device of claim 22, wherein the interconnect includes a pad coupled to the integrated passive device and a via that extends through a cavity in the passive device interposer.

24. The device of claim 22, wherein the passive device interposer includes more than one integrated passive device.

25. The device of claim 22, wherein the passive device interposer is configured to be electrically coupled to the integrated device through at least the interconnect, the solder interconnect, and a pillar interconnect.

26. The device of claim 22, wherein the passive device interposer has a lateral size that is approximately the same or less, than the lateral size of the integrated device.

27. The device of claim 22, wherein the integrated device includes a die having a front side and back side.

28. The device of claim 27, wherein the plurality of pillar interconnects and the passive device interposer are coupled to the front side of the die.

29. The device of claim 22, wherein the integrated device comprises:
a die having a front side and back side; and
a metallization portion coupled to the front side of the die.

30. The device of claim 29, wherein plurality of pillar interconnects and the passive device interposer are coupled to the metallization portion.
